(19) United States
(12) Patent Application Publication
(10) Pub. No.: US 2024/0244750 A1
(43) Pub. Date: Jul. 18, 2024

(54) SEMICONDUCTOR MODULE

(71) Applicant: ROHM CO., LTD., Kyoto-shi (JP)

(72) Inventor: Masashi HAYASHIGUCHI, Kyoto-shi (JP)

(21) Appl. No.: 18/429,848

(22) Filed: Feb. 1, 2024

Related U.S. Application Data
(63) Continuation of application No. PCT/JP2022/032371, filed on Aug. 29, 2022.

(30) Foreign Application Priority Data
Sep. 21, 2021 (JP) 2021-153457

(51) Int. Cl. H05K 1/14; H01L 23/00; H01L 23/40; H01L 23/498; H01L 25/11; H01R 12/71; H05K 1/18

(52) U.S. Cl. CPC H05K 1/144; H01L 23/49811; H01L 25/115; H05K 1/18; H01L 23/40; H01L 24/37; H01L 24/40; H01L 24/45; H01L 24/48; H01L 2224/37011; H01L 2224/37147; H01L 2224/40137; H01L 2224/40225; H01L 2224/45124; H01L 2224/45144; H01L 2224/45147; H01L 2224/48225; H01R 12/718; H05K 2201/10166; H05K 2201/10871

(57) ABSTRACT

A semiconductor module includes: a plurality of semiconductor devices that each include a signal terminal extending in a first direction, and that is electrically connected to a semiconductor element; a heat sink; a plurality of first wiring boards that are electrically connected to the plurality of signal terminals of the respective semiconductor devices; and a second wiring board electrically connected to the plurality of first wiring boards. The signal terminal of one of the plurality of semiconductor devices is press-fitted into one of the plurality of first wiring boards in the first direction. The semiconductor module further includes a plurality of communication wirings electrically connecting the plurality of first wiring boards and the second wiring board. The plurality of communication wirings are displaceable in a direction perpendicular to the first direction.

### TECHNICAL FIELD

The present disclosure relates to a semiconductor module, and in particular to a semiconductor module in which a plurality of semiconductor devices are assembled to a heat sink and a wiring board.

### BACKGROUND ART

JP-A-2016-162773 discloses an example of a semiconductor device (power module) in which a plurality of semiconductor elements are electrically bonded to a conductor layer. The semiconductor device is electrically connected to a plurality of signal terminals. The signal terminals protrude from a sealing resin in a thickness direction.

When the semiconductor device disclosed in JP-A-2016-162773 is used, a wiring board for driving and controlling the semiconductor device is connected to the signal terminals. In general, the wiring board is connected to a plurality of semiconductor devices. The wiring board has a plurality of connecting holes. After the signal terminals are inserted in the respective connecting holes, solder is used to electrically connect the wiring board to the signal terminals. At this stage, vibrations transmitted from the outside to the wiring board may cause cracks in the solder that electrically connects the signal terminals and the wiring board.

To address this issue, it is possible to employ press-fitting instead of solder to electrically connect the signal terminals and the wiring board, so that the connection therebetween becomes more resistant against vibrations. In this case, however, as the number of signal terminals increases, misalignment of the wiring board relative to the direction in which the signal terminals extend is less likely to be allowable. As a result, it may become more difficult to connect the wiring board to the signal terminals.

### BRIEF DESCRIPTION OF THE DRAWINGS

FIG. 1 is a plan view showing a semiconductor module according to a first embodiment of the present disclosure.

FIG. 2 is a front view showing the semiconductor module in FIG. 1.

FIG. 3 is a partially enlarged view of FIG. 1.

FIG. 4 is a partially enlarged view of FIG. 2.

FIG. 5A is a partially enlarged cross-sectional view showing a first wiring board in FIG. 4.

FIG. 5B is a partially enlarged cross-sectional view showing the first wiring board in FIG. 4, and shows a different configuration from that shown in FIG. 5A.

FIG. 6 is a partially enlarged cross-sectional view showing a communication wiring in FIG. 4.

FIG. 7 is a block diagram showing the circuits provided on the first wiring board in FIG. 4.

FIG. 8 is a perspective view showing one of a plurality of semiconductor devices constituting the semiconductor module in FIG. 1.

FIG. 9 is a plan view showing the semiconductor device in FIG. 8.

FIG. 10 is a plan view corresponding to FIG. 9, with a sealing resin shown as transparent.

FIG. 11 is a partially enlarged view of FIG. 10.

FIG. 12 is a plan view corresponding to FIG. 9, where a first conducting member is shown as transparent and the sealing resin and a second conducting member are omitted.

FIG. 13 is a right-side view showing the semiconductor device in FIG. 1.

FIG. 14 is a bottom view showing the semiconductor device in FIG. 1.

FIG. 15 is a cross-sectional view along line XV-XV in FIG. 10.

FIG. 16 is a cross-sectional view along line XVI-XVI in FIG. 10.

FIG. 17 is a partially enlarged view showing a first element and an area around the first element in FIG. 16.

FIG. 18 is a partially enlarged view showing a second element and an area around the second element in FIG. 16.

FIG. 19 is a cross-sectional view along line XIX-XIX in FIG. 10.

FIG. 20 is a cross-sectional view along line XX-XX in FIG. 10.

FIG. 21 is a partially enlarged front view showing a first variation of the semiconductor module in FIG. 1.

FIG. 22 is a partially enlarged front view showing a second variation of the semiconductor module in FIG. 1.

FIG. 23 is a partially enlarged plan view showing a semiconductor module according to a second embodiment of the present disclosure.

FIG. 24 is a partially enlarged front view showing the semiconductor module in FIG. 23.

FIG. 25 is a plan view showing one of a plurality of semiconductor devices constituting the semiconductor module in FIG. 23.

FIG. 26 is a cross-sectional view along line XXVI-XXVI in FIG. 25.

FIG. 27 is a partially enlarged plan view showing a semiconductor module according to a third embodiment of the present disclosure.

FIG. 28 is a partially enlarged front view showing the semiconductor module in FIG. 27.

FIG. 29 is a perspective view showing one of a plurality of semiconductor devices constituting the semiconductor module in FIG. 27.

FIG. 30 is a plan view showing a semiconductor device in FIG. 29.

FIG. 31 is a cross-sectional view along line XXXI-XXXI in FIG. 30.

FIG. 32 is a partially enlarged plan view showing a semiconductor module according to a fourth embodiment of the present disclosure.

FIG. 33 is a partially enlarged front view showing the semiconductor module in FIG. 32.

FIG. 34 is a cross-sectional view along line XXXIV-XXXIV in FIG. 32.

FIG. 35 is a partially enlarged plan view showing a semiconductor module according to a fifth embodiment of the present disclosure.

FIG. 36 is a partially enlarged front view showing the semiconductor module in FIG. 35.

FIG. 37 is a cross-sectional view along line XXXVII-XXXVII in FIG. 35.

### DETAILED DESCRIPTION OF EMBODIMENTS

The following describes embodiments of the present disclosure with reference to the accompanying drawings.

### First Embodiment

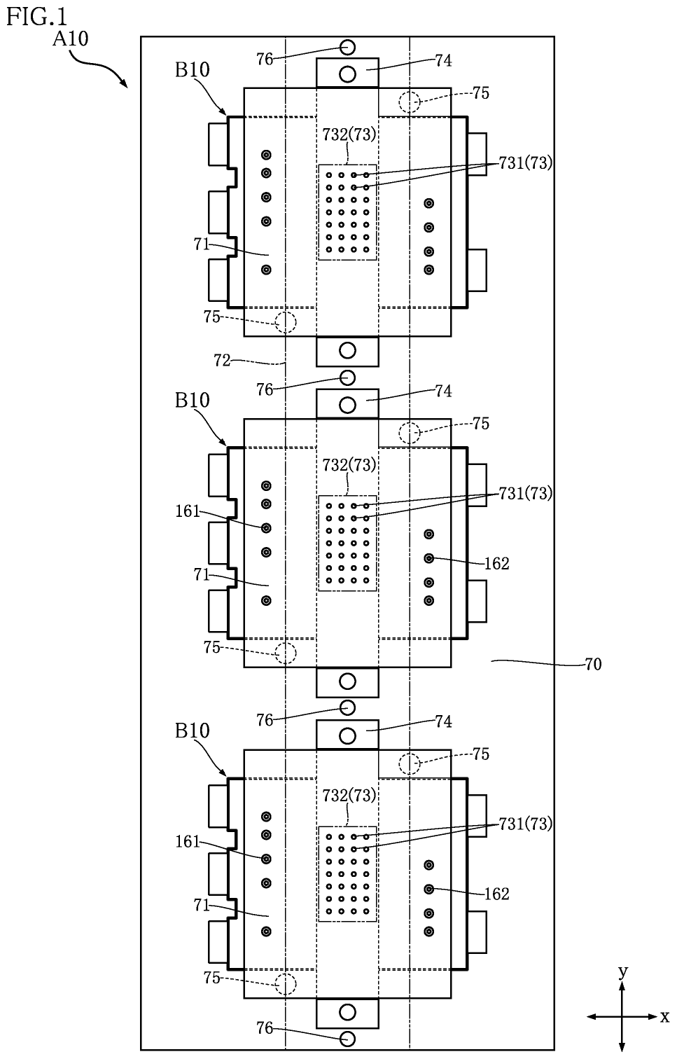

The following describes a semiconductor module A10 according to a first embodiment of the present disclosure with reference to FIGS. 1 to 20. For convenience, the description of the semiconductor module A10 will be provided after a description of a plurality of semiconductor devices B10 that constitute the semiconductor module A10.

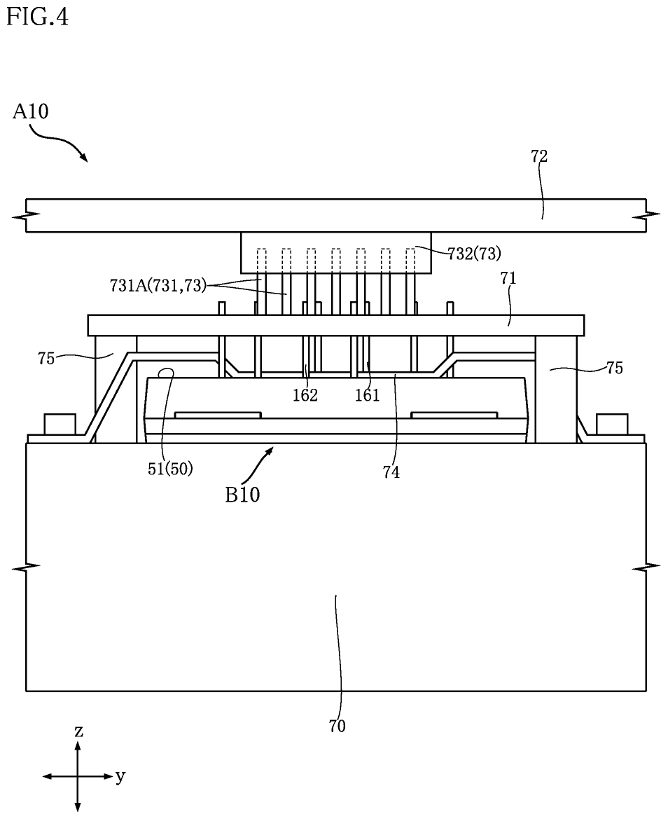

In the description of the semiconductor module A10, the direction in which first signal terminals 161 (described below) of the semiconductor devices B10 extend will be referred to as “first direction z” (see FIG. 4) for convenience. A direction perpendicular to the first direction z will be referred to as “second direction x”. The direction perpendicular to both of the first direction z and the second direction x will be referred to as “third direction y”.

### Semiconductor Devices B10

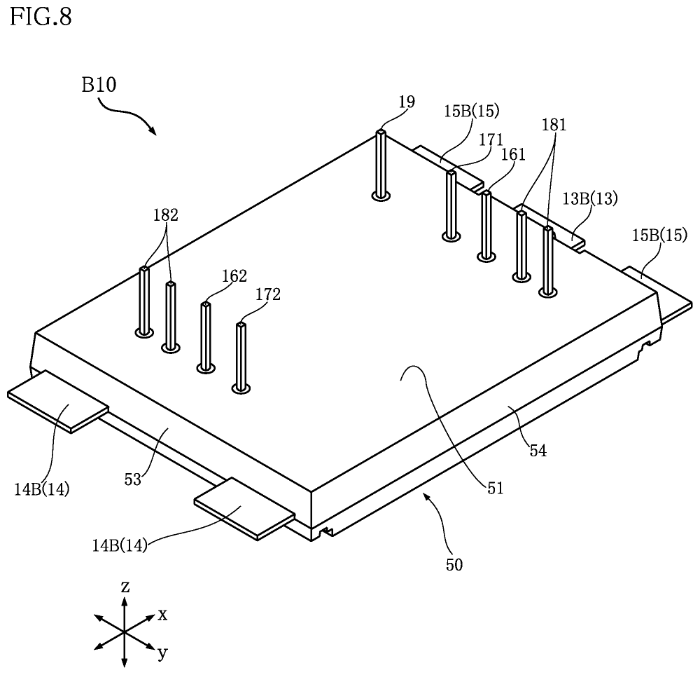

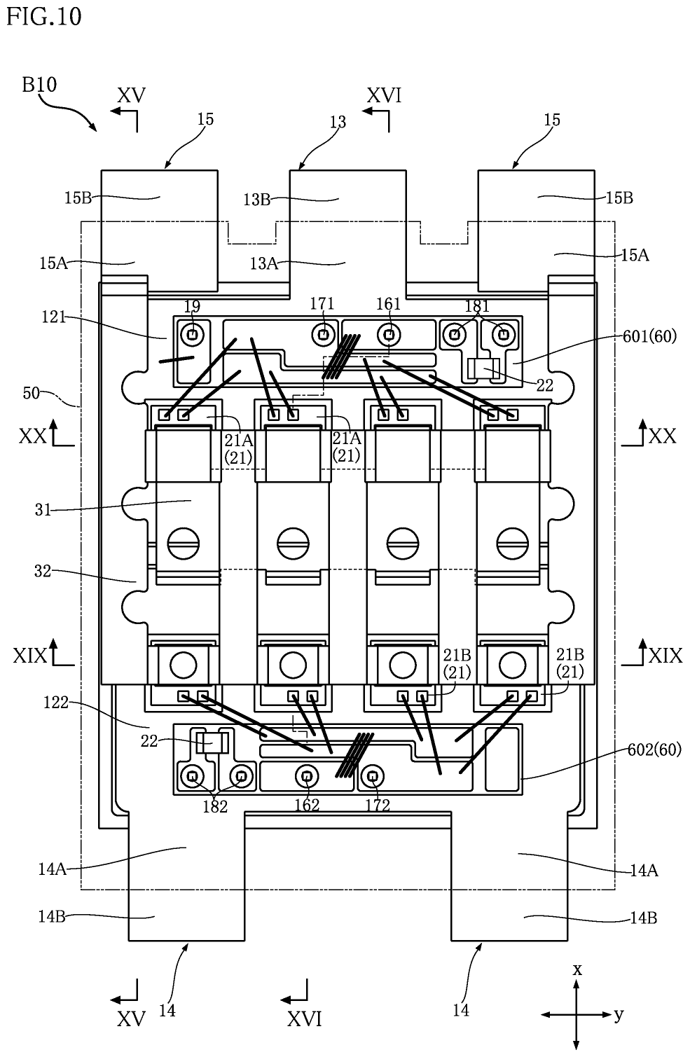

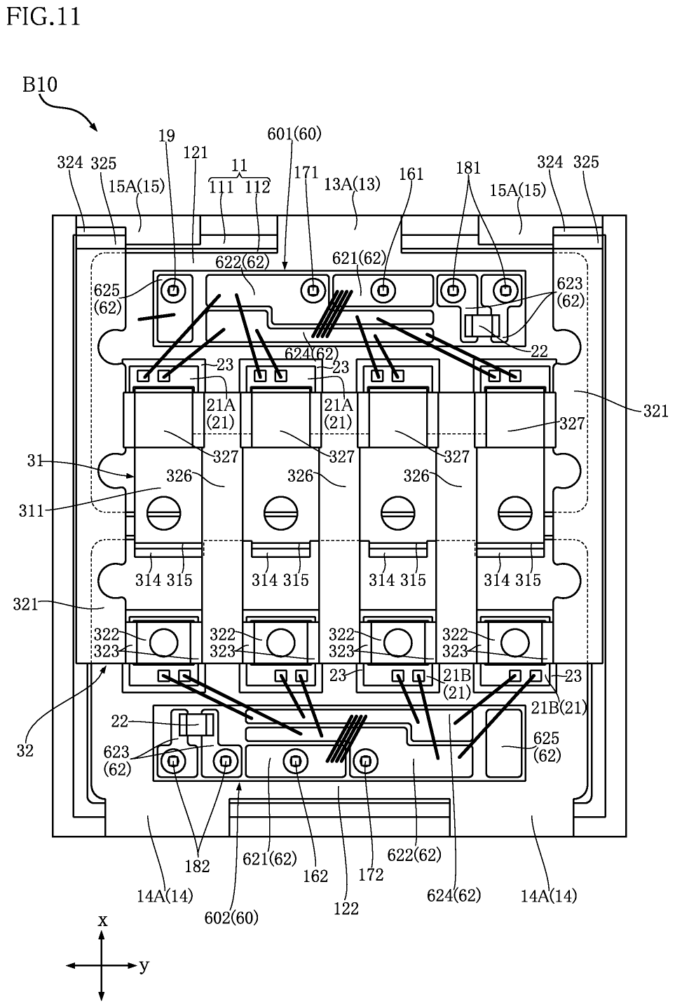

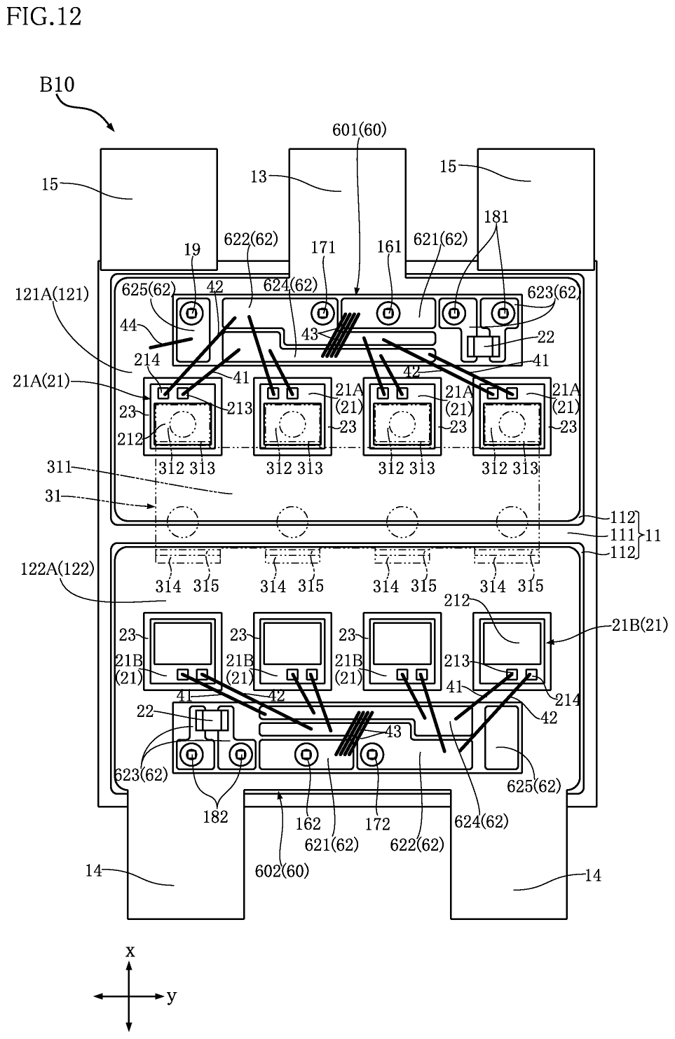

The following describes a plurality of semiconductor devices B10 that constitute the semiconductor module A10, with reference to FIGS. 8 to 20. The semiconductor devices B10 are identical to each other. Each of the semiconductor devices B10 includes a support 11, a first conductive layer 121, a second conductive layer 122, a first input terminal 13, an output terminal 14, a second input terminal 15, a first signal terminal 161, a second signal terminal 162, a plurality of semiconductor elements 21, a first conducting member 31, a second conducting member 32, and a sealing resin 50. Each of the semiconductor devices B10 further includes a third signal terminal 171, a fourth signal terminal 172, a pair of fifth signal terminals 181, a pair of sixth signal terminals 182, a seventh signal terminal 19, a pair of thermistors 22, and a pair of control wirings 60. In FIGS. 10 and 11, the sealing resin 50 is shown as transparent for convenience of understanding. The sealing resin 50 in FIG. 10 is indicated by an imaginary line (two-dot chain line). For convenience, FIG. 12 shows the first conducting member 31 as transparent and omits the second conducting member 32 and the sealing resin 50.

The semiconductor device B10 uses the semiconductor elements 21 to convert the DC source voltage applied to the first input terminal 13 and the second input terminal 15 into AC power. The AC power obtained by the conversion is inputted from the output terminal 14 to a power-supply target such as a motor.

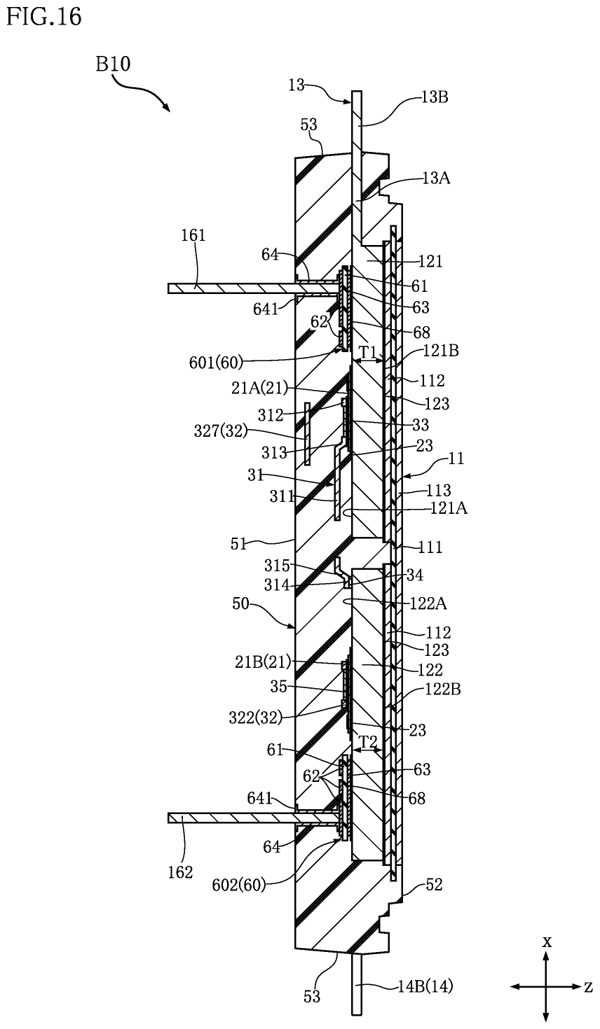

As shown in FIGS. 16 to 18, the support 11 is located opposite from the semiconductor elements 21 with the first conductive layer 121 and the second conductive layer 122 therebetween in the first direction z. The support 11 supports the first conductive layer 121 and the second conductive layer 122. In the semiconductor device B10, the support 11 comprises a direct bonded copper (DBC) substrate. As shown in FIGS. 16 to 18, the support 11 includes an insulating layer 111, an intermediate layer 112, and a heat dissipation layer 113. The support 11 is covered with the sealing resin 50 except a portion of the heat dissipation layer 113.

As shown in FIGS. 16 to 18, the insulating layer 111 includes a portion interposed between the intermediate layer 112 and the heat dissipation layer 113 in the first direction z. The insulating layer 111 is made of a material having a relatively high thermal conductivity. The insulating layer 111 is made of ceramics containing aluminum nitride (AlN), for example. The insulating layer 111 may be made of an insulating resin sheet instead of ceramics. The insulating layer 111 is thinner than each of the first conductive layer 121 and the second conductive layer 122.

As shown in FIGS. 16 to 18, the intermediate layer 112 is located between the insulating layer 111 and each of the first conductive layer 121 and the second conductive layer 122 in the first direction z. The intermediate layer 112 includes a pair of regions spaced apart from each other in the second direction x. The composition of the intermediate layer 112 includes copper (Cu). In other words, the intermediate layer 112 contains copper. As shown in FIG. 12, the intermediate layer 112 is surrounded by the periphery of the insulating layer 111 as viewed in the first direction z.

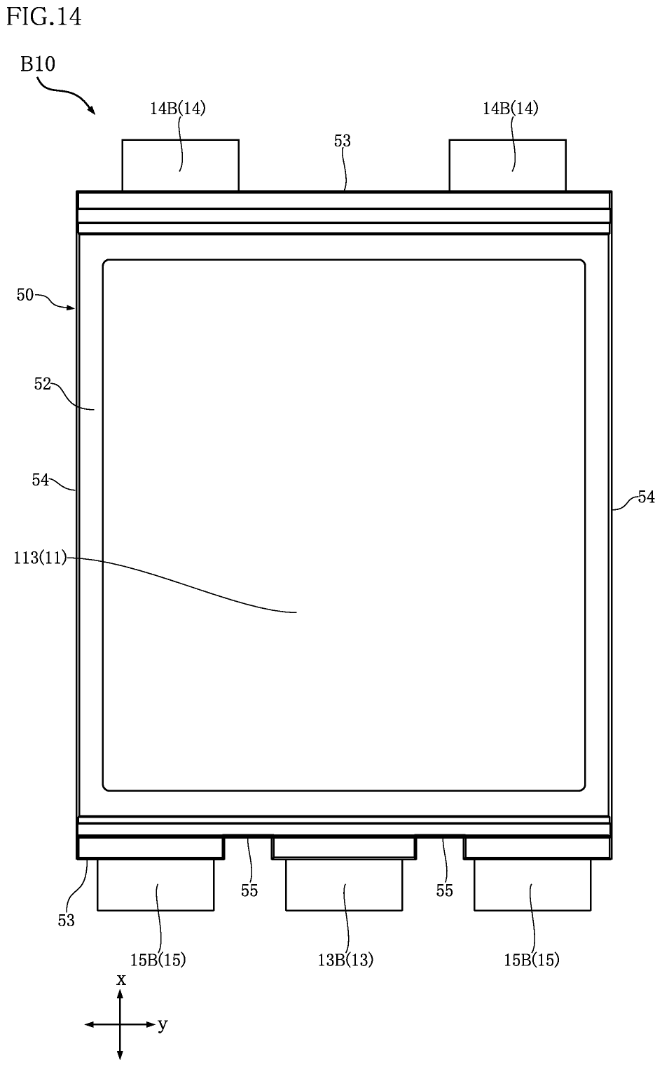

As shown in FIGS. 16 to 18, the heat dissipation layer 113 is located opposite from the intermediate layer 112 with the insulating layer 111 therebetween in the first direction z. As shown in FIG. 14, the heat dissipation layer 113 is exposed from the sealing resin 50. The heat dissipation layer 113 is bonded to a heat sink 70 described below. The composition of the heat dissipation layer 113 includes copper. The heat dissipation layer 113 is thicker than the insulating layer 111. As viewed in the first direction z, the heat dissipation layer 113 is surrounded by the periphery of the insulating layer 111.

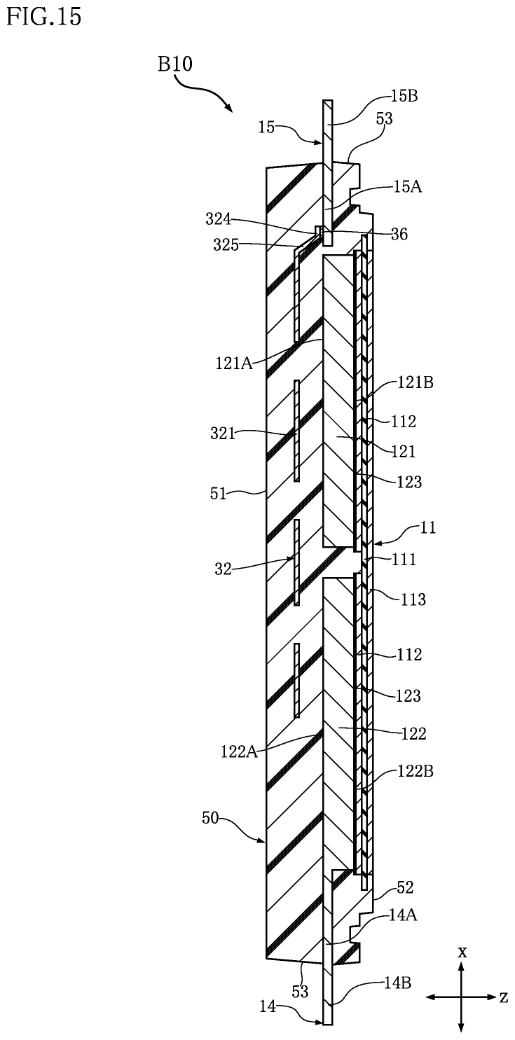

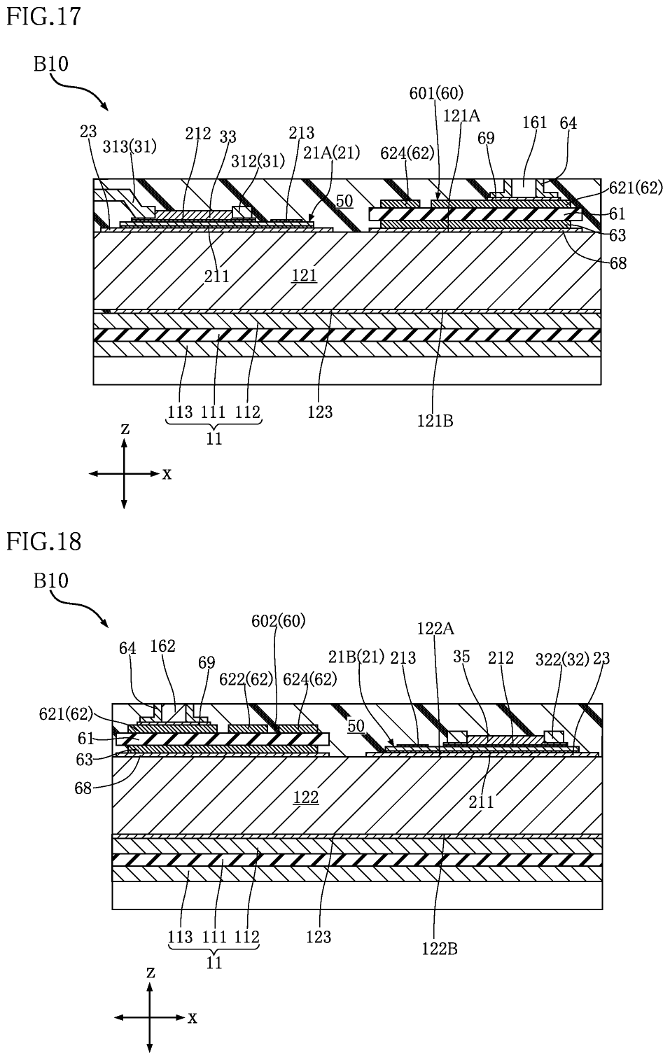

As shown in FIGS. 16 to 18, the first conductive layer 121 and the second conductive layer 122 are bonded to the support 11. The composition of the first conductive layer 121 and the second conductive layer 122 includes copper. The first conductive layer 121 and the second conductive layer 122 are spaced part from each other in the second direction x. As shown in FIGS. 15 and 16, the first conductive layer 121 has a first obverse surface 121A and a first reverse surface 121B that face away from each other in the first direction z. The first obverse surface 121A faces the semiconductor elements 21. As shown in FIG. 17, the first reverse surface 121B is bonded to one of the pair of regions of the intermediate layer 112 via a first adhesive layer 123. The first adhesive layer 123 may be made of a brazing material including silver (Ag) in its composition. As shown in FIGS. 15 and 16, the second conductive layer 122 has a second obverse surface 122A and a second reverse surface 122B that face away from each other in the first direction z. The second obverse surface 122A faces the same side as the first obverse surface 121A in the first direction z. As shown in FIG. 18, the second reverse surface 122B is bonded to the other one of the pair of regions of the intermediate layer 112 via the first adhesive layer 123.

As shown in FIGS. 12 and 16, each of the semiconductor elements 21 is mounted on one of the first conductive layer 121 and the second conductive layer 122. The semiconductor elements 21 are metal-oxide-semiconductor field-effect transistors (MOSFETs), for example. Alternatively, the semiconductor elements 21 may be switching elements, such as insulated gate bipolar transistors (IGBTs), or diodes. In the illustrated semiconductor device B10, the semiconductor elements 21 are n-channel MOSFETs each having a vertical structure. Each of the semiconductor elements 21 includes a compound semiconductor substrate. The composition of the compound semiconductor substrate includes silicon carbide (SiC).

As shown in FIG. 12, the semiconductor elements 21 include a plurality of first elements 21A and a plurality of second elements 21B. Each of the second elements 21B has the same structure as each of the first elements 21A. The first elements 21A are mounted on the first obverse surface 121A of the first conductive layer 121. The first elements 21A are arranged in the third direction y. The second elements 21B are mounted on the second obverse surface 122A of the second conductive layer 122. The second elements 21B are arranged in the third direction y.

As shown in FIGS. 12, 17 and 18, each of the semiconductor elements 21 has a first electrode 211, a second electrode 212, a third electrode 213, and a fourth electrode 214.

As shown in FIGS. 17 and 18, the first electrode 211 faces one of the first conductive layer 121 and the second conductive layer 122. The current flowing through the first electrode 211 corresponds to the electric power that has yet to be converted by the semiconductor element 21. In other words, the first electrode 211 corresponds to the drain electrode of the semiconductor element 21.

As shown in FIGS. 17 and 18, the second electrode 212 is located opposite from the first electrode 211 in the first direction z. The current flowing through the second electrode 212 corresponds to the electric power that has been converted by the semiconductor element 21. In other words, the second electrode 212 corresponds to the source electrode of the semiconductor element 21.

As shown in FIGS. 17 and 18, the third electrode 213 is located on the same side as the second electrode 212 in the first direction z. A gate voltage for driving the semiconductor element 21 is applied to the third electrode 213. In other words, the third electrode 213 corresponds to the gate electrode of the semiconductor element 21. As shown in FIG. 12, the area of the third electrode 213 is smaller than the area of the second electrode 212 as viewed in the first direction z.

As shown in FIG. 12, the fourth electrode 214 is located on the same side as the second electrode 212 in the first direction z, and is arranged next to the third electrode 213 in the third direction y. The potential of the fourth electrode 214 is equal to the potential of the second electrode 212.

As shown in FIGS. 17 and 18, conductive bonding layers 23 are each interposed between one of the first conductive layer 121 and the second conductive layer 122 and the first electrode 211 of one of the semiconductor elements 21. Each of the conductive bonding layers 23 is solder, for example. Alternatively, the conductive bonding layers 23 may contain sintered metal particles. The first electrodes 211 of the first elements 21A are electrically bonded to the first obverse surface 121A of the first conductive layer 121 via the conductive bonding layers 23. As a result, the first electrodes 211 of the first elements 21A are electrically connected to the first conductive layer 121. The first electrodes 211 of the second elements 21B are electrically bonded to the second obverse surface 122A of the second conductive layer 122 via the conductive bonding layers 23. As a result, the first electrodes 211 of the second elements 21B are electrically connected to the second conductive layer 122.

As shown in FIGS. 10 and 16, the first input terminal 13 is located opposite from the second conductive layer 122 with the first conductive layer 121 therebetween in the second direction x, and is connected to the first conductive layer 121. As a result, the first input terminal 13 is electrically connected to the first electrodes 211 of the first elements 21A via the first conductive layer 121. The first input terminal 13 is a P terminal (positive electrode) to which the DC source voltage targeted for power conversion is applied. The first input terminal 13 extends from the first conductive layer 121 in the second direction x. The first input terminal 13 has a covered portion 13A and an exposed portion 13B. As shown in FIG. 16, the covered portion 13A is connected to the first conductive layer 121, and is covered with the sealing resin 50. The covered portion 13A is flush with the first obverse surface 121A of the first conductive layer 121. The exposed portion 13B extends from the covered portion 13A in the second direction x, and is exposed from the sealing resin 50. The first input terminal 13 is thinner than the first conductive layer 121.

As shown in FIGS. 10 and 15, the output terminal 14 is located opposite from the first conductive layer 121 with the second conductive layer 122 therebetween in the second direction x, and is connected to the second conductive layer 122. As a result, the output terminal 14 is electrically connected to the first electrodes 211 of the second elements 21B via the second conductive layer 122. The AC power resulting from the conversion by the semiconductor elements 21 is outputted from the output terminal 14. In the semiconductor device B10, the output terminal 14 includes a pair of regions spaced apart from each other in the third direction y. Alternatively, the output terminal 14 may be a single element not including the pair of regions. The output terminal 14 has a covered portion 14A and an exposed portion 14B. As shown in FIG. 15, the covered portion 14A is connected to the second conductive layer 122, and is covered with the sealing resin 50. The covered portion 14A is flush with the second obverse surface 122A of the second conductive layer 122. The exposed portion 14B extends from the covered portion 14A in the second direction x, and is exposed from the sealing resin 50. The output terminal 14 is thinner than the second conductive layer 122.

As shown in FIGS. 10 and 15, the second input terminal 15 is located on the same side as the first input terminal 13 with respect to the first conductive layer 121 and the second conductive layer 122 in the second direction x, is away from the first conductive layer 121 and the second conductive layer 122. The second input terminal 15 is electrically connected to the second electrodes 212 of the second elements 21B. The second input terminal 15 is an N terminal (negative electrode) to which the DC source voltage targeted for power conversion is applied. The second input terminal 15 includes a pair of regions spaced apart from each other in the third direction y. The first input terminal 13 is positioned between the pair of regions in the third direction y. The second input terminal 15 has a covered portion 15A and an exposed portion 15B. As shown in FIG. 15, the covered portion 15A is spaced apart from the first conductive layer 121, and is covered with the sealing resin 50. The exposed portion 15B extends from the covered portion 15A in the second direction x, and is exposed from the sealing resin 50.

The pair of control wirings 60 form a portion of a conductive path connecting the first signal terminal 161, the second signal terminal 162, the third signal terminal 171, the fourth signal terminal 172, the pair of fifth signal terminals 181, and the pair of sixth signal terminals 182 to the semiconductor elements 21. As shown in FIGS. 10 to 12, the pair of control wirings 60 include a first wiring 601 and a second wiring 602. In the second direction x, the first wiring 601 is located between the first elements 21A and each of the first input terminal 13 and the second input terminal 15. The first wiring 601 is bonded to the first obverse surface 121A of the first conductive layer 121. The first wiring 601 also forms a portion of a conductive path between the seventh signal terminal 19 and the first conductive layer 121. In the second direction x, the second wiring 602 is located between the second elements 21B and the output terminal 14. The second wiring 602 is bonded to the second obverse surface 122A of the second conductive layer 122. As shown in FIGS. 17 and 18, each of the pair of control wirings 60 includes an insulating layer 61, a plurality of wiring layers 62, a metal layer 63, and a plurality of sleeves 64. The pair of control wirings 60 are covered with the sealing resin 50 except a portion of each sleeve 64.

As shown in FIGS. 17 and 18, the insulating layer 61 includes a portion interposed between the wiring layers 62 and the metal layer 63 in the first direction z. The insulating layer 61 is made of ceramics, for example. The insulating layer 61 may be made of an insulating resin sheet instead of ceramics.

As shown in FIGS. 17 and 18, the wiring layers 62 are located on one side of the insulating layer 61 in the first direction z. The composition of the wiring layers 62 includes copper. As shown in FIG. 12, each of the wiring layers 62 include a first wiring layer 621, a second wiring layer 622, a pair of third wiring layers 623, a fourth wiring layer 624, and a fifth wiring layer 625. The pair of third wiring layers 623 are adjacent to each other in the third direction y.

As shown in FIGS. 17 and 18, the metal layer 63 is located opposite from the wiring layers 62 with the insulating layer 61 therebetween in the first direction z. The composition of the metal layer 63 includes copper. The metal layer 63 of the first wiring 601 is bonded to the first obverse surface 121A of the first conductive layer 121 by a second adhesive layer 68. The metal layer 63 of the second wiring 602 is bonded to the second obverse surface 122A of the second conductive layer 122 by the second adhesive layer 68. The second adhesive layer 68 may be made of a conductive or a non-conductive material. The second adhesive layer 68 is made of solder, for example.

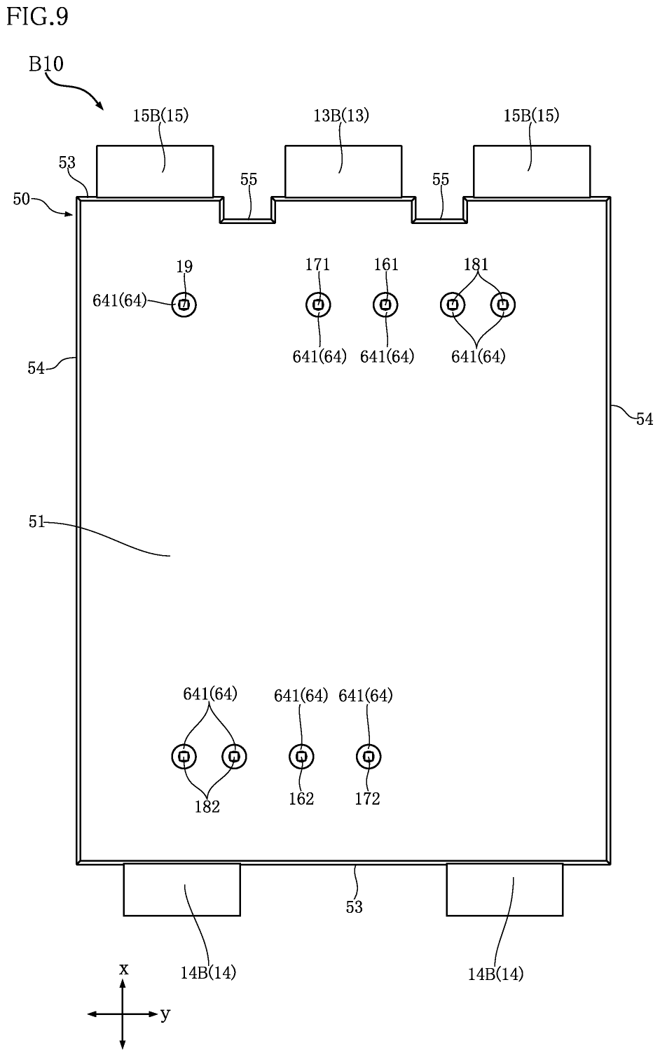

As shown in FIGS. 17 and 18, each of the sleeves 64 is bonded to one of the wiring layers 62 by a third adhesive layer 69. The sleeves 64 are made of a conductive material such as metal. Each of the sleeves 64 has a tubular shape extending in the first direction z. An end of each sleeve 64 is electrically bonded to one of the wiring layers 62. As shown in FIGS. 9 and 16, an end surface 641 corresponding to the other end of each sleeve 64 is exposed from a top surface 51 (described below) of the sealing resin 50. The third adhesive layer 69 has electrical conductivity. The third adhesive layer 69 is made of solder, for example.

As shown in FIG. 11, one of the pair of thermistors 22 is electrically bonded to the pair of third wiring layers 623 of the first wiring 601. As shown in FIG. 11, the other one of the pair of thermistors 22 is electrically bonded to the pair of third wiring layers 623 of the second wiring 602. The pair of thermistors 22 are negative temperature coefficient (NTC) thermistors, for example. The NTC thermistors have a characteristic that the resistance is lowered gradually as the temperature rises. The pair of thermistors 22 are used as temperature detection sensors for the semiconductor device B10.

As shown in FIG. 8, the first signal terminal 161, the second signal terminal 162, the third signal terminal 171, the fourth signal terminal 172, the pair of fifth signal terminals 181, the pair of sixth signal terminals 182, and the seventh signal terminal 19 are made of metal pins extending in the first direction z. These terminals protrude from the top surface 51 (described below) of the sealing resin 50. Furthermore, these terminals are press-fitted into the respective sleeves 64 of the pair of control wirings 60. Thus, each of the terminals is supported by one of the sleeves 64, and is electrically connected to one of the wiring layers 62.

As shown in FIGS. 12 and 17, the first signal terminal 161 is press-fitted into the sleeve 64 bonded to the first wiring layer 621 of the first wiring 601, among the sleeves 64 of the pair of control wirings 60. Thus, the first signal terminal 161 is supported by the sleeve 64, and is electrically connected to the first wiring layer 621 of the first wiring 601. Furthermore, the first signal terminal 161 is electrically connected to the third electrodes 213 of the first elements 21A. A gate voltage for driving the first elements 21A is applied to the first signal terminal 161.

As shown in FIGS. 12 and 18, the second signal terminal 162 is press-fitted into the sleeve 64 bonded to the first wiring layer 621 of the second wiring 602, among the sleeves 64 of the pair of control wirings 60. Thus, the second signal terminal 162 is supported by the sleeve 64, and is electrically connected to the first wiring layer 621 of the second wiring 602. Furthermore, the second signal terminal 162 is electrically connected to the third electrodes 213 of the second elements 21B. A gate voltage for driving the second elements 21B is applied to the second signal terminal 162.

As shown in FIG. 9, the third signal terminal 171 is located adjacent to the first signal terminal 161 in the third direction y. As shown in FIG. 12, the third signal terminal 171 is press-fitted into the sleeve 64 bonded to the second wiring layer 622 of the first wiring 601, among the sleeves 64 of the pair of control wirings 60. Thus, the third signal terminal 171 is supported by the sleeve 64, and is electrically connected to the second wiring layer 622 of the first wiring 601. Furthermore, the third signal terminal 171 is electrically connected to the fourth electrodes 214 of the first elements 21A. A voltage corresponding to the current that is the highest of the currents flowing through the respective fourth electrodes 214 of the first elements 21A is applied to the third signal terminal 171.

As shown in FIG. 9, the fourth signal terminal 172 is located adjacent to the second signal terminal 162 in the third direction y. As shown in FIG. 12, the fourth signal terminal 172 is press-fitted into the sleeve 64 bonded to the second wiring layer 622 of the second wiring 602, among the sleeves 64 of the pair of control wirings 60. Thus, the fourth signal terminal 172 is supported by the sleeve 64, and is electrically connected to the second wiring layer 622 of the second wiring 602. Furthermore, the fourth signal terminal 172 is electrically connected to the fourth electrodes 214 of the second elements 21B. A voltage corresponding to the current that is the highest of the currents flowing through the respective fourth electrodes 214 of the second elements 21B is applied to the fourth signal terminal 172.

As shown in FIG. 9, the pair of fifth signal terminals 181 are located opposite from the third signal terminal 171 with the first signal terminal 161 therebetween in the third direction y. The pair of fifth signal terminals 181 are adjacent to each other in the third direction y. As shown in FIG. 12, the pair of fifth signal terminals 181 are press-fitted into the pair of sleeves 64 bonded to the pair of third wiring layers 623 of the first wiring 601, among the sleeves 64 of the pair of control wirings 60. Thus, the pair of fifth signal terminals 181 are supported by the pair of sleeves 64, and are electrically connected to the pair of third wiring layers 623 of the first wiring 601. Furthermore, the pair of fifth signal terminals 181 are electrically connected to one of the pair of thermistors 22 that is electrically bonded to the pair of third wiring layers 623 of the first wiring 601.

As shown in FIG. 9, the pair of sixth signal terminals 182 are located opposite from the fourth signal terminal 172 with the second signal terminal 162 therebetween in the third direction y. The pair of sixth signal terminals 182 are adjacent to each other in the third direction y. As shown in FIG. 12, the pair of sixth signal terminals 182 are press-fitted into the pair of sleeves 64 bonded to the pair of third wiring layers 623 of the second wiring 602, among the sleeves 64 of the pair of control wirings 60. Thus, the pair of sixth signal terminals 182 are supported by the pair of sleeves 64, and are electrically connected to the pair of third wiring layers 623 of the second wiring 602. Furthermore, the pair of sixth signal terminals 182 are electrically connected to one of the pair of thermistors 22 that is electrically bonded to the pair of third wiring layers 623 of the second wiring 602.

As shown in FIG. 9, the seventh signal terminal 19 is located opposite from the first signal terminal 161 with the third signal terminal 171 therebetween in the third direction y. As shown in FIG. 12, the seventh signal terminal 19 is press-fitted into the sleeve 64 bonded to the fifth wiring layer 625 of the first wiring 601, among the sleeves 64 of the pair of control wirings 60. Thus, the seventh signal terminal 19 is supported by the sleeve 64, and is electrically connected to the fifth wiring layer 625 of the first wiring 601. Furthermore, the seventh signal terminal 19 is electrically connected to the first conductive layer 121. A voltage corresponding to the DC power inputted to the first input terminal 13 and the second input terminal 15 is applied to the seventh signal terminal 19.

As shown in FIG. 12, a plurality of first wires 41 are electrically bonded to the third electrodes 213 of the first elements 21A and the fourth wiring layer 624 of the first wiring 601. As shown in FIG. 12, a plurality of third wires 43 are electrically bonded to the fourth wiring layer 624 of the first wiring 601 and the first wiring layer 621 of the first wiring 601. Thus, the first signal terminal 161 is electrically connected to the third electrodes 213 of the first elements 21A. The composition of the first wires 41 and the third wires 43 includes gold (Au). Alternatively, the composition of the first wires 41 and the third wires 43 may include copper or aluminum.

Furthermore, as shown in FIG. 12, a plurality of first wires 41 are electrically bonded to the third electrodes 213 of the second elements 21B and the fourth wiring layer 624 of the second wiring 602. Furthermore, as shown in FIG. 12, a plurality of third wires 43 are electrically bonded to the fourth wiring layer 624 of the second wiring 602 and the first wiring layer 621 of the second wiring 602. Thus, the second signal terminal 162 is electrically connected to the third electrodes 213 of the second elements 21B.

As shown in FIG. 12, a plurality of second wires 42 are electrically bonded to the fourth electrodes 214 of the first elements 21A and the second wiring layer 622 of the first wiring 601. Thus, the third signal terminal 171 is electrically connected to the fourth electrodes 214 of the first elements 21A. Furthermore, as shown in FIG. 12, a plurality of second wires 42 are electrically bonded to the fourth electrodes 214 of the second elements 21B and the second wiring layer 622 of the second wiring 602. Thus, the fourth signal terminal 172 is electrically connected to the fourth electrodes 214 of the second elements 21B. The composition of the second wires 42 includes gold. Alternatively, the composition of the second wires 42 may include copper or aluminum.

As shown in FIG. 12, a fourth wire 44 is electrically bonded to the fifth wiring layer 625 of the first wiring 601 and the first obverse surface 121A of the first conductive layer 121. Thus, the seventh signal terminal 19 is electrically connected to the first conductive layer 121. The composition of the fourth wire 44 includes gold. Alternatively, the composition of the fourth wire 44 may include copper or aluminum.

As shown in FIGS. 12 and 17, the first conducting member 31 is electrically bonded to the second electrodes 212 of the first elements 21A and the second obverse surface 122A of the second conductive layer 122. Thus, the second electrodes 212 of the first elements 21A are electrically connected to the second conductive layer 122. The composition of the first conducting member 31 includes copper. The first conducting member 31 is a metal clip. As shown in FIG. 12, the first conducting member 31 has a main body 311, a plurality of first bonding portions 312, a plurality of first connecting portions 313, a second bonding portion 314, and a second connecting portion 315.

The main body 311 forms a main part of the first conducting member 31. As shown in FIG. 12, the main body 311 extends in the third direction y. As shown in FIG. 16, the main body 311 bridges the gap between the first conductive layer 121 and the second conductive layer 122.

As shown in FIG. 17, the first bonding portions 312 are bonded to the second electrodes 212 of the respective first elements 21A. Each of the first bonding portions 312 faces the second electrode 212 of one of the first elements 21A.

As shown in FIG. 12, the first connecting portions 313 are connected to the main body 311 and the first bonding portions 312. The first connecting portions 313 are spaced apart from each other in the third direction y. As shown in FIG. 16, as viewed in the third direction y, the first connecting portions 313 are inclined in a direction away from the first obverse surface 121A of the first conductive layer 121 as proceeding from the first bonding portions 312 toward the main body 311.

As shown in FIGS. 12 and 16, the second bonding portion 314 is bonded to the second obverse surface 122A of the second conductive layer 122. The second bonding portion 314 faces the second obverse surface 122A. The second bonding portion 314 extends in the third direction y. The second bonding portion 314 has the same dimension as the main body 311 in the third direction y.

As shown in FIGS. 12 and 16, the second connecting portion 315 is connected to the main body 311 and the second bonding portion 314. As viewed in the third direction y, the second connecting portion 315 is inclined in a direction away from the second obverse surface 122A of the second conductive layer 122 as proceeding from the second bonding portion 314 toward the main body 311. The second connecting portion 315 has the same dimension as the main body 311 in the third direction y.

As shown in FIGS. 16, 17, and 20, the semiconductor device B10 further includes a first conductive bonding layer 33. The first conductive bonding layer 33 is interposed between the second electrodes 212 of the first elements 21A and the first bonding portions 312. The first conductive bonding layer 33 electrically bonds the second electrodes 212 of the first elements 21A and the first bonding portions 312 to each other. The first conductive bonding layer 33 is made of solder, for example. Alternatively, the first conductive bonding layer 33 may contain sintered metal particles.

As shown in FIG. 16, the semiconductor device B10 further includes a second conductive bonding layer 34. The second conductive bonding layer 34 is interposed between the second obverse surface 122A of the second conductive layer 122 and the second bonding portion 314. The second conductive bonding layer 34 electrically bonds the second obverse surface 122A and the second bonding portion 314 to each other. The second conductive bonding layer 34 is made of solder, for example. Alternatively, the second conductive bonding layer 34 may contain sintered metal particles.

As shown in FIGS. 11 and 18, the second conducting member 32 is electrically bonded to the second electrodes 212 of the second elements 21B and the covered portion 15A of the second input terminal 15. Thus, the second electrodes 212 of the second elements 21B are electrically connected to the second input terminal 15. The composition of the second conducting member 32 includes copper. The second conducting member 32 is a metal clip. As shown in FIG. 11, the second conducting member 32 includes a pair of main bodies 321, a plurality of third bonding portions 322, a plurality of third connecting portions 323, a pair of fourth bonding portions 324, a pair of fourth connecting portions 325, a pair of intermediate portions 326, and a plurality of beam portions 327.

As shown in FIG. 11, the pair of main bodies 321 are spaced part from each other in the third direction y. The pair of main bodies 321 extend in the second direction x. As shown in FIG. 15, the pair of main bodies 321 are arranged parallel to the first obverse surface 121A of the first conductive layer 121 and the second obverse surface 122A of the second conductive layer 122. The pair of main bodies 321 are located farther away from the first obverse surface 121A and the second obverse surface 122A than the main body 311 of the first conducting member 31.

As shown in FIG. 11, the intermediate portions 326 are spaced apart from each other in the third direction y, and are located between the pair of main bodies 321 in the third direction y. The intermediate portions 326 extend in the second direction x. Each of the intermediate portions 326 has a dimension smaller than each of the pair of main bodies 321 in the second direction x.

As shown in FIG. 18, the third bonding portions 322 are bonded to the second electrodes 212 of the second elements 21B. Each of the third bonding portions 322 faces the second electrode 212 of one of the second elements 21B.

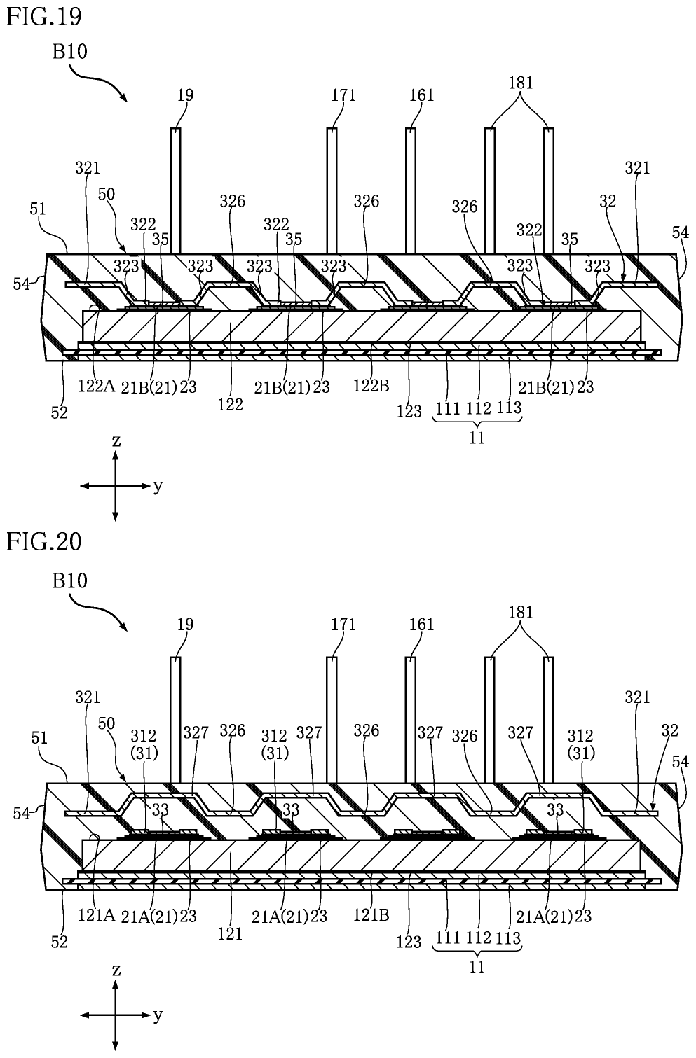

As shown in FIGS. 11 and 19, the third connecting portions 323 are connected to the sides of the respective third bonding portions 322 in the third direction y. Furthermore, each of the third connecting portions 323 is connected to one of the pair of main bodies 321 and the intermediate portions 326. As viewed in the second direction x, each of the third connecting portions 323 is inclined in a direction away from the second obverse surface 122A of the second conductive layer 122 as proceeding from one of the third bonding portions 322 toward one of the pair of main bodies 321 and the intermediate portions 326.

As shown in FIGS. 11 and 15, the pair of fourth bonding portions 324 are bonded to the covered portion 15A of the second input terminal 15. The pair of fourth bonding portions 324 face the covered portion 15A.

As shown in FIGS. 11 and 15, the pair of fourth connecting portions 325 are connected to the pair of main bodies 321 and the pair of fourth bonding portions 324. As viewed in the third direction y, the pair of fourth connecting portions 325 are inclined in a direction away from the first obverse surface 121A of the first conductive layer 121 as proceeding from the pair of fourth bonding portions 324 toward the pair of main bodies 321.

As shown in FIGS. 11 and 20, the beam portions 327 are arranged in the third direction y. As viewed in the first direction z, the beam portions 327 include areas overlapping with the respective first bonding portions 312 of the first conducting member 31. Of the beam portions 327, both sides of each of the beam portions 327 located at the center are connected to the intermediate portions 326. Both sides of each of the remaining two beam portions 327 in the third direction y are connected to one of the pair of main bodies 321 and one of the intermediate portions 326, respectively. As viewed in the second direction x, the beam portions 327 protrude in the sense of the first direction z in which the first obverse surface 121A of the first conductive layer 121 faces.

As shown in FIGS. 16, 18, and 19, the semiconductor device B10 further includes a third conductive bonding layer 35. The third conductive bonding layer 35 is interposed between the second electrodes 212 of the second elements 21B and the third bonding portions 322. The third conductive bonding layer 35 electrically bonds the second electrodes 212 of the second elements 21B and the third bonding portions 322 to each other. The third conductive bonding layer 35 is made of solder, for example. Alternatively, the third conductive bonding layer 35 may contain sintered metal particles.

As shown in FIG. 15, the semiconductor device B10 further includes a fourth conductive bonding layer 36. The fourth conductive bonding layer 36 is interposed between the covered portion 15A of the second input terminal 15 and the pair of fourth bonding portions 324. The fourth conductive bonding layer 36 electrically bonds the covered portion 15A and the pair of fourth bonding portions 324 to each other. The fourth conductive bonding layer 36 is made of solder, for example. Alternatively, the fourth conductive bonding layer 36 may contain sintered metal particles.

As shown in FIGS. 15, 16, 19, and 20, the sealing resin 50 covers the first conductive layer 121, the second conductive layer 122, the semiconductor elements 21, the first conducting member 31, and the second conducting member 32. The sealing resin 50 further covers a portion of each of the support 11, the first input terminal 13, the output terminal 14, and the second input terminal 15. The sealing resin 50 is electrically insulative. The sealing resin 50 is made of a material containing black epoxy resin, for example. As shown in FIGS. 9 and FIGS. 13 to 16, the sealing resin 50 has a top surface 51, a bottom surface 52, a pair of first side surfaces 53, a pair of second side surfaces 54, and a pair of recesses 55.

As shown in FIGS. 15 and 16, the top surface 51 faces the same side as the first obverse surface 121A of the first conductive layer 121 in the first direction z. As shown in FIGS. 15 and 16, the bottom surface 52 faces away from the top surface 51 in the first direction z. As shown in FIG. 14, the heat dissipation layer 113 of the support 11 is exposed from the bottom surface 52.

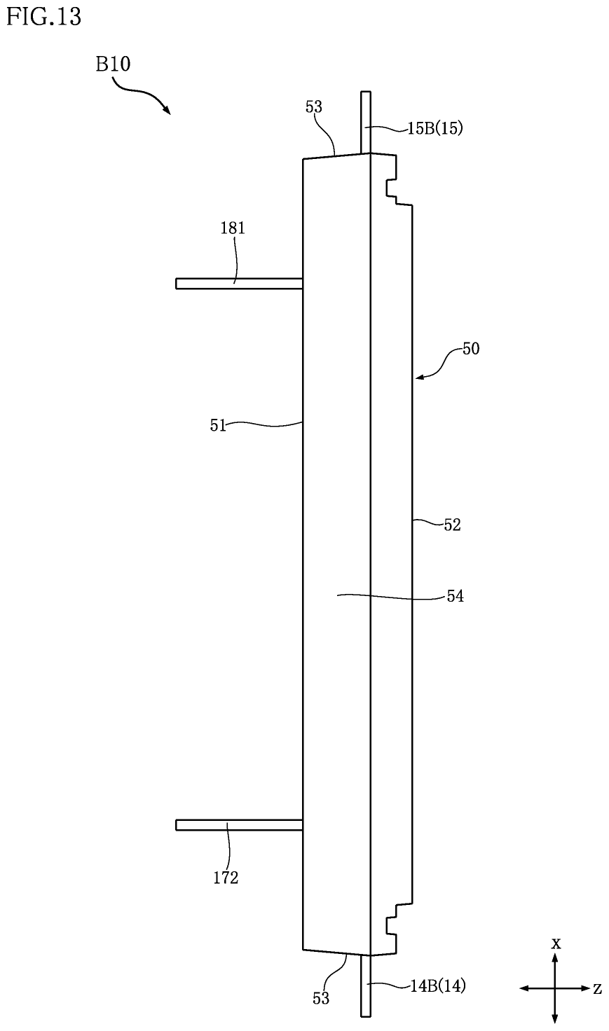

As shown in FIGS. 9 and 13, the pair of first side surfaces 53 are spaced apart from each other in the second direction x. The pair of first side surfaces 53 face in the second direction x and extend in the third direction y. The pair of first side surfaces 53 are connected to the top surface 51. The exposed portion 13B of the first input terminal 13 and the exposed portion 15B of the second input terminal 15 are exposed from one of the pair of first side surfaces 53. The exposed portion 14B of the output terminal 14 is exposed from the other one of the pair of first side surfaces 53.

As shown in FIGS. 9 and 14, the pair of second side surfaces 54 are spaced apart from each other in the third direction y. The pair of second side surfaces 54 face away from each other in the third direction y and extend in the second direction x. The pair of second side surfaces 54 are connected to the top surface 51 and the bottom surface 52.

As shown in FIGS. 9 and 14, the pair of recesses 55 are recessed in the second direction x from the first side surface 53 from which the exposed portion 13B of the first input terminal 13 and the exposed portion 15B of the second input terminal 15 are exposed. The pair of recesses 55 extend from the top surface 51 to the bottom surface 52 in the first direction z. The pair of recesses 55 flank the first input terminal 13 in the third direction y.

### Semiconductor Module A10

Next, the semiconductor module A10 will be described with reference to FIGS. 1 to 7. The semiconductor module A10 includes the semiconductor devices B10 described above, a heat sink 70, a plurality of first wiring boards 71, a second wiring board 72, a plurality of communication wirings 73, a plurality of mounting members 74, a plurality of support members 75, and a plurality of positioning pins 76. The semiconductor module A10 is used in an inverter for driving a three-phase AC motor, for example.

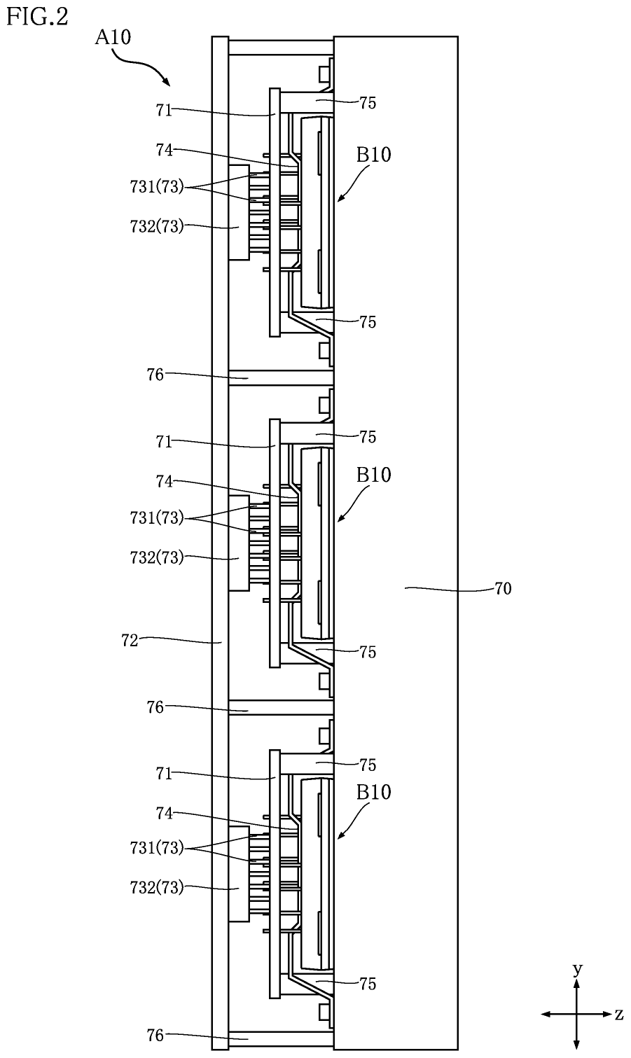

As shown in FIGS. 1 and 2, the heat sink 70 supports the semiconductor devices B10. The heat sink 70 is located opposite from the first signal terminals 161 and the second signal terminals 162 of the semiconductor devices B10 with respect to the semiconductor elements 21 of the semiconductor devices B10 (see FIGS. 2 and 20). Thus, the heat sink 70 faces the heat dissipation layers 113 of the semiconductor devices B10. The heat sink 70 is made of a material containing aluminum, for example. The semiconductor devices B10 are arranged in the third direction y on the heat sink 70.

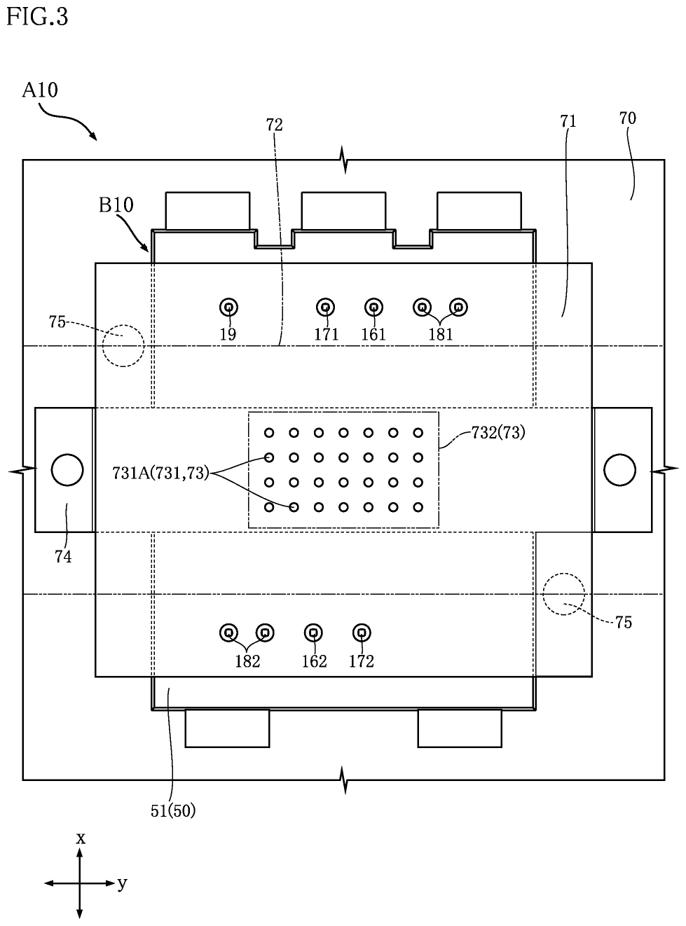

As shown in FIG. 3, each of the first wiring boards 71 is electrically connected to the first signal terminal 161, the second signal terminal 162, the third signal terminal 171, the fourth signal terminal 172, the pair of fifth signal terminals 181, the pair of sixth signal terminals 182, and the seventh signal terminal 19 of one of the semiconductor devices B10. As shown in FIG. 4, each of the first wiring boards 71 faces the top surface 51 of the sealing resin 50 of one of the semiconductor devices B10. The first wiring boards 71 are located opposite from the heat sink 70 with respect to the semiconductor elements 21 of the semiconductor devices B10 (see FIGS. 2 and 20). As viewed in the first direction z, each of the first wiring boards 71 overlaps with the sealing resin 50 of one of the semiconductor devices B10.

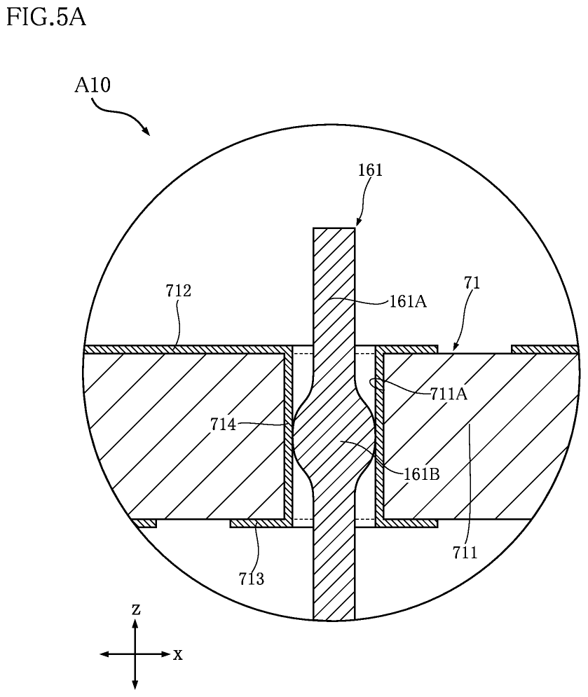

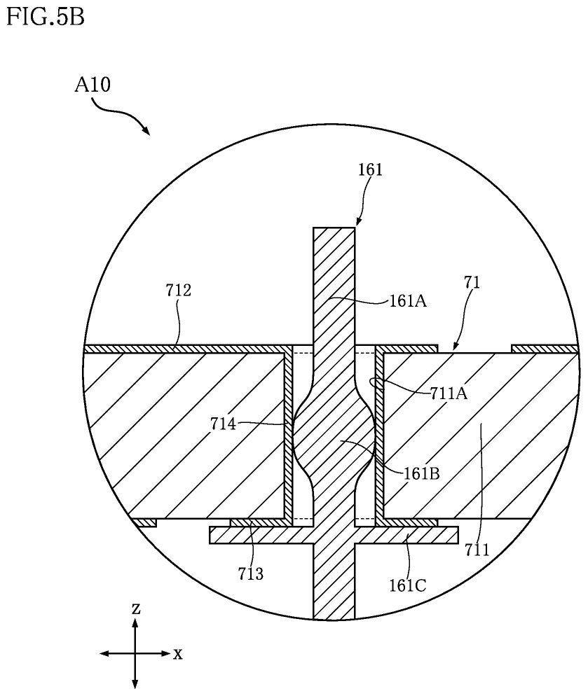

As shown in FIG. 5A, each of the first wiring boards 71 includes a substrate 711, an obverse wiring 712, a reverse wiring 713, and an internal wiring 714. The substrate 711 has a plurality of through-holes 711A formed therethrough in the first direction z. The obverse wiring 712 is arranged on one side of the substrate 711 in the first direction z, and faces the second wiring board 72. The reverse wiring 713 is arranged on the other side of the substrate 711 in the first direction z. The internal wiring 714 is arranged in the through-holes 711A. The internal wiring 714 is connected to the obverse wiring 712 and the reverse wiring 713. The obverse wiring 712 forms a path that allows electrical connection between the internal wiring 714, a circuit provided on the first wiring board 71, and the communication wiring 73 electrically connected to the circuit.

As shown in FIG. 5A, the first signal terminal 161 of each semiconductor device B10 has a base 161A and a bulging portion 161B. One side of the base 161A in the first direction z is press-fitted into one of the sleeves 64 of the semiconductor device B10. The bulging portion 161B is provided on the other side of the base 161A in the first direction z. The bulging portion 161B bulges in a direction perpendicular to the first direction z.

As shown in FIG. 5A, the first signal terminal 161 of each semiconductor device B10 is press-fitted into one of the through-holes 711A of the first wiring board 71. Thus, the internal wiring 714 arranged in one of the through-holes 711A is pressed against the bulging portion 161B of the first signal terminal 161. Accordingly, the first signal terminal 161 of the semiconductor device B10 is electrically connected to the first wiring board 71 by being press-fitted into the first wiring board 71 in the first direction z. The second signal terminal 162, the third signal terminal 171, the fourth signal terminal 172, the pair of fifth signal terminals 181, the pair of sixth signal terminals 182, and the seventh signal terminal 19 of each semiconductor device B10 are similar to the first signal terminal 161 in terms of the base 161A and the bulging portion 161B. Thus, these signal terminals are also press-fitted into the first wiring board 71 in the first direction z to be electrically connected to the first wiring board 71.

FIG. 5B shows a configuration of the first signal terminal 161 of each semiconductor device B10, which is different from the configuration shown in FIG. 5A. The first signal terminal 161 has a seating portion 161C, in addition to the base 161A and the bulging portion 161B. When the first signal terminal 161 is press-fitted into one of the through-holes 711A in the first wiring board 71, the internal wiring 714 arranged in the through-hole 711A is pressed against the bulging portion 161B, and the seating portion 161C comes into contact with the reverse wiring 713.

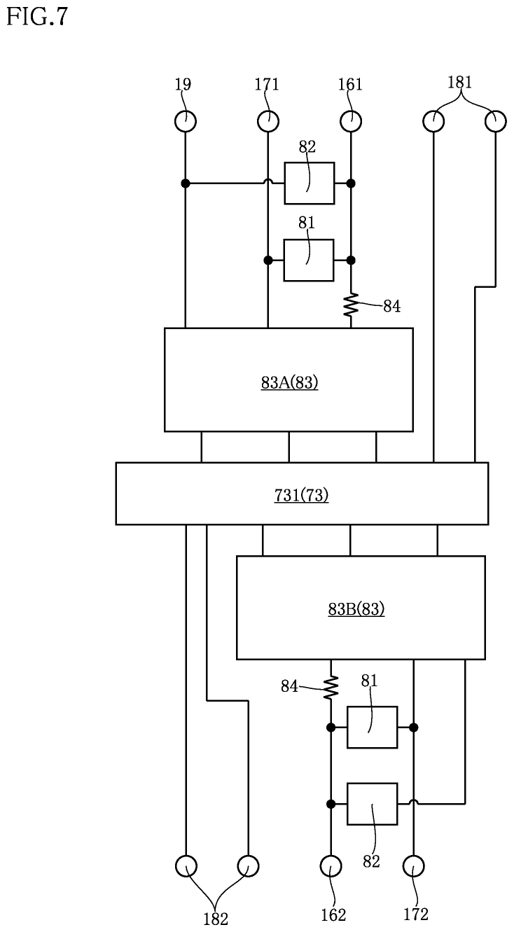

As shown in FIG. 7, each of the first wiring boards 71 is provided with a pair of first protection circuits 81, a pair of second protection circuits 82, a pair of gate drivers 83, and a pair of gate resistors 84.

One of the pair of first protection circuits 81 is electrically connected to the first signal terminal 161 and the third signal terminal 171 of the semiconductor device B10. The other one of the pair of first protection circuits 81 is connected to the second signal terminal 162 and the fourth signal terminal 172. The pair of first protection circuits 81 suppress the application of overvoltage to the third electrodes 213 of the semiconductor elements 21 in the semiconductor device B10. In general, the pair of first protection circuits 81 include snubber circuits.

One of the pair of second protection circuits 82 is electrically connected to the first signal terminal 161 and the seventh signal terminal 19 of the semiconductor device B10. The other one of the pair of second protection circuits 82 is electrically connected to the second signal terminal 162 and a second driver 83B described below. The pair of second protection circuits 82 suppress the application of surge voltage to the semiconductor elements 21 in the semiconductor device B10. In general, the pair of second protection circuits 82 include clamp circuits.

The pair of gate drivers 83 include a first driver 83A and a second driver 83B. The first driver 83A is electrically connected to one of the first protection circuits 81 and one of the second protection circuits 82, and drives the first elements 21A of the semiconductor device B10. The second driver 83B is electrically connected to the other one of the first protection circuits 81 and the other one of the second protection circuits 82, and drives the second elements 21B of the semiconductor device B10. One of the pair of gate resistors 84 is provided in the conductive path between the first driver 83A and the first signal terminal 161. The other one of the pair of gate resistors 84 is provided in the conductive path between the second driver 83B and the second signal terminal 162.

In the semiconductor module A10, at least a pair of first protection circuits 81 are provided on each of the first wiring boards 71. Accordingly, the pair of second protection circuits 82, the pair of gate drivers 83, and the pair of gate resistors 84 may be provided on the second wiring board 72.

As shown in FIG. 2, the second wiring board 72 is electrically connected to the first wiring boards 71 via the communication wirings 73. As shown in FIG. 1, the second wiring board 72 extends in the third direction y. The second wiring board 72 is provided with circuits that are not provided on the first wiring boards 71, and that drive and control the semiconductor devices B10. One example of such circuits is a controller for controlling the pair of gate drivers 83. The second wiring board 72 is further provided with an overheat protection circuit electrically connected to the pair of thermistors 22 in each semiconductor device B10. The second wiring board 72 is located opposite from the heat sink 70 with the first wiring boards 71 therebetween in the first direction z. As viewed in the first direction z, the second wiring board 72 overlaps with the first wiring boards 71.

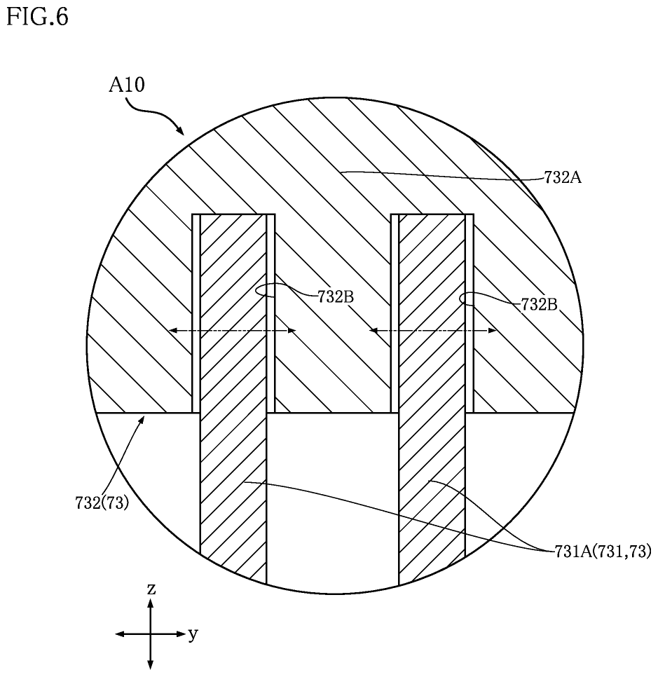

As shown in FIG. 2, the communication wirings 73 electrically connect the first wiring boards 71 and the second wiring board 72 to each other. In the semiconductor module A10, each of the communication wirings 73 includes a first connecting portion 731 and a second connecting portion 732. As shown in FIG. 3, the first connecting portion 731 is electrically bonded to one of the first wiring boards 71. As shown in FIGS. 3 and 4, the first connecting portion 731 includes a plurality of connecting pins 731A. The connecting pins 731A extend in the first direction z. As shown in FIG. 4, the second connecting portion 732 is electrically bonded to the second wiring board 72 and faces the first connecting portion 731. As shown in FIG. 6, the second connecting portion 732 has a housing 732A and a plurality of connecting holes 732B. The connecting pins 731A are inserted in the respective connecting holes 732B. As a result, the first connecting portion 731 is electrically connected to the second connecting portion 732.

As shown in FIG. 6, the housing 732A of the second connecting portion 732 can be displaced relative to the connecting pins 731A in a direction perpendicular to the first direction z. This allows the second connecting portion 732 to be displaced relative to the first connecting portion 731 in a direction perpendicular to the first direction z. Thus, the communication wirings 73 are configured to be displaceable in a direction perpendicular to the first direction z. Such a configuration of the communication wirings 73 is realized by adopting the configuration of a known connector disclosed in JP-A-2018-113163, JP-A-2018-63886, or JP-A-2017-139101, for example.

As shown in FIGS. 1 and 2, the mounting members 74 are used to restrain the semiconductor devices B10 at the heat sink 70. The mounting members 74 are conductors containing metal. Each of the mounting members 74 is in contact with and extends across the top surface 51 of the sealing resin 50 of one of the semiconductor devices B10. The mounting members 74 are plate springs, for example. Each of the mounting members 74 is located between the first signal terminal 161 and the second signal terminal 162 of one of the semiconductor devices B10 in the second direction x. The mounting members 74 are located between the heat sink 70 and the first wiring boards 71 in the first direction z.

As shown in FIG. 2, the support members 75 are located between the heat sink 70 and the first wiring boards 71 in the first direction z. The first wiring boards 71 are supported by the support members 75. Each of the support members 75 has a columnar shape. As shown in FIG. 3, each of the support members 75 is spaced apart from the top surface 51 of the sealing resin 50 of one of the semiconductor devices B10, as viewed in the first direction z.

As shown in FIG. 2, the positioning pins 76 are located between the heat sink 70 and the second wiring board 72 in the first direction z. The positioning pins 76 are arranged in the third direction y. Each of the positioning pins 76 is located between two semiconductor devices B10 that are adjacent to each other in the third direction y. The positioning pins 76 are used to position the second wiring board 72 relative to the heat sink 70, and to support the second wiring board 72.

### First Variation

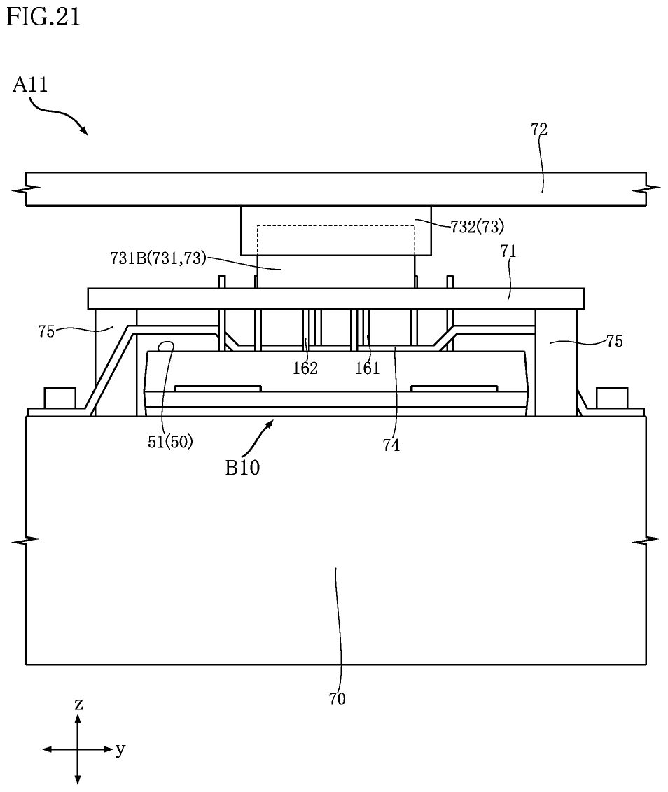

Next, a semiconductor module A11, which is a first variation of the semiconductor module A10, will be described with reference to FIG. 21.

The semiconductor module A11 is different from the semiconductor module A10 in the configuration of the communication wirings 73. As shown in FIG. 21, the first connecting portion 731 of each communication wiring 73 has a housing 731B. The housing 731B houses the connecting pins 731A shown in FIG. 4. When the first connecting portion 731 is electrically connected to the second connecting portion 732, an end of the housing 731B in the first direction z is housed in the housing 732A of the second connecting portion 732.

### Second Variation

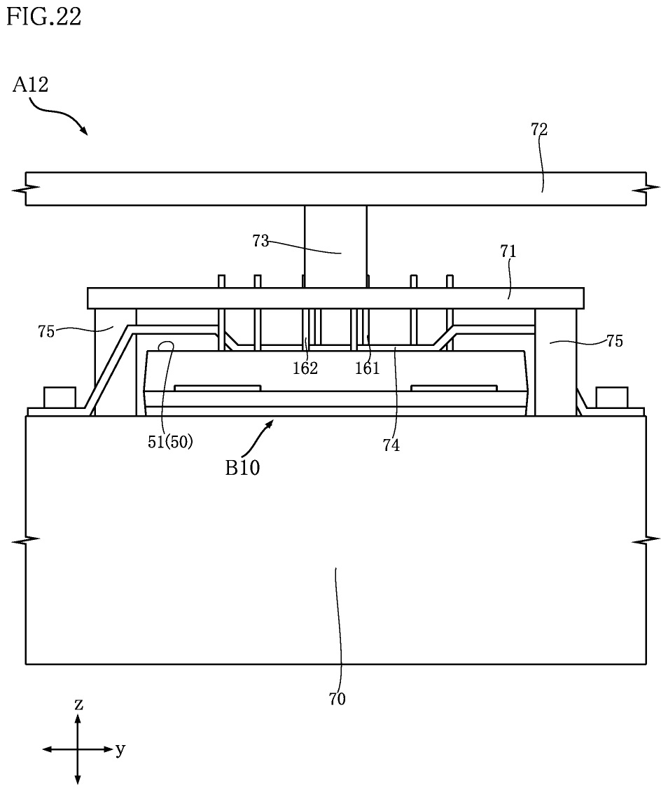

Next, a semiconductor module A12, which is a second variation of the semiconductor module A10, will be described with reference to FIG. 22.

The semiconductor module A12 is different from the semiconductor module A10 in the configuration of the communication wirings 73. As shown in FIG. 22, each of the communication wirings 73 has an integral structure, instead of a separate structure with the first connecting portion 731 and the second connecting portion 732 as seen in the semiconductor module A10. The communication wirings 73 have flexibility capable of being displaced in a direction perpendicular to the first direction z. The communication wirings 73 are flexible, for example.

The following describes advantages of the semiconductor module A10.

The semiconductor module A10 includes the first wiring boards 71 electrically connected to the first signal terminals 161 of the respective semiconductor devices B10, and the second wiring board 72 electrically connected to the first wiring boards 71. The first signal terminals 161 of the semiconductor devices B10 are press-fitted into the respective first wiring boards 71 in the first direction z. This makes it possible to connect the first wiring boards 71 more firmly to the first signal terminals 161 of the semiconductor devices B10. In this case, the semiconductor module A10 further includes the communication wirings 73 that electrically connect the first wiring boards 71 and the second wiring board 72. The communication wirings 73 are displaceable in a direction perpendicular to the first direction z. Thus, even if the second wiring board 72 is misaligned in a direction perpendicular to the first direction z with respect to the first wiring boards 71, the communication wirings 73 are displaced to allow the misalignment of the second wiring board 72. As such, the semiconductor module A10 can allow misalignment of the wiring board (the second wiring board 72) in a direction perpendicular to the direction in which the first signal terminals 161 extend, while connecting the wiring boards (the first wiring boards 71) more firmly to the first signal terminals 161 of the respective semiconductor devices B10.

The second wiring board 72 is located opposite from the heat sink 70 with the first wiring boards 71 therebetween in the first direction z. This makes it possible to arrange the first wiring boards 71 and the second wiring board 72 more compactly without interfering with the heat sink 70.

The semiconductor module A10 further includes the support members 75 located between the heat sink 70 and the first wiring boards 71 in the first direction z and supporting the first wiring boards 71. As viewed in the first direction z, each of the support members 75 is spaced apart from the top surface 51 of the sealing resin 50 of one of the semiconductor devices B10. This makes it possible to suppress a decrease in the dielectric strength of the semiconductor devices B10 caused by the support members 75 when the support members 75 are conductors.

Each of the semiconductor devices B10 includes a support 11 located opposite from semiconductor elements 21 with a first conductive layer 121 and a second conductive layer 122 therebetween. The first conductive layer 121 and the second conductive layer 122 are bonded to the support 11. The support 11 includes an insulating layer 111, and a heat dissipation layer 113 located opposite from the first conductive layer 121 and the second conductive layer 122 with the insulating layer 111 therebetween. This allows the heat transmitted from the first elements 21A and the second elements 21B to the first conductive layer 121 and the second conductive layer 122 to be efficiently released outside the semiconductor device B10, while using the first conductive layer 121 and the second conductive layer 122 as conductive paths in the semiconductor device B10. In this case, it is preferable that the heat dissipation layer 113 be thicker than the insulating layer 111, because the heat conduction efficiency of the heat dissipation layer 113 in a direction perpendicular to the first direction z is improved, resulting in the improvement of heat dissipation of the semiconductor device B10.

The sealing resin 50 of each semiconductor device B10 has a pair of recesses 55 recessed in the second direction x from one of the pair of first side surfaces 53 from which the first input terminal 13 and the second input terminal 15 are exposed. The pair of recesses 55 flank the first input terminal 13 in the third direction y. This increases the creepage distance of the sealing resin 50 between the first input terminal 13 and the second input terminal 15. As a result, the dielectric strength of the semiconductor device B10 is improved.

### Second Embodiment

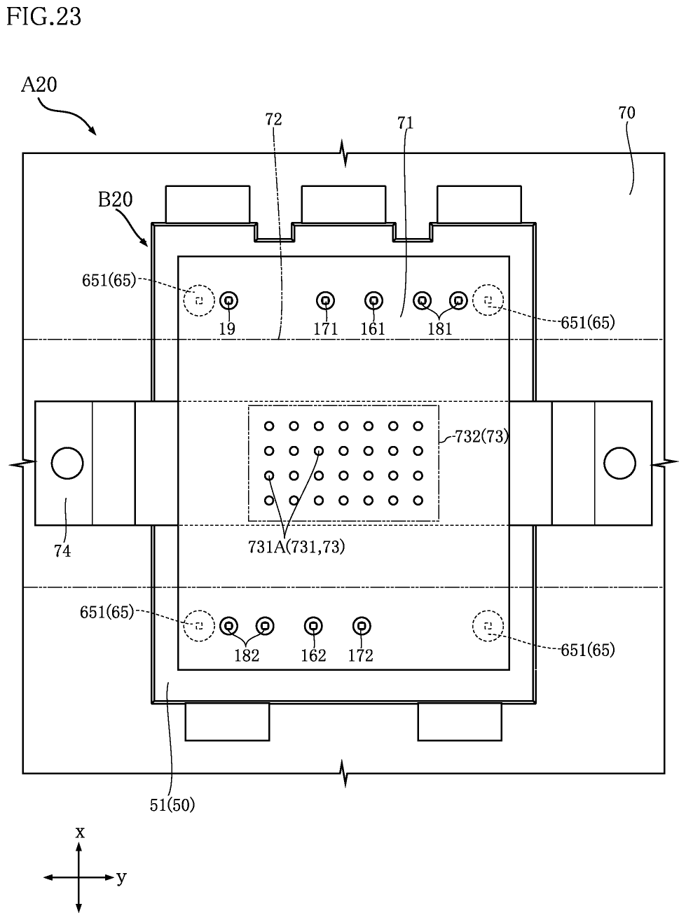

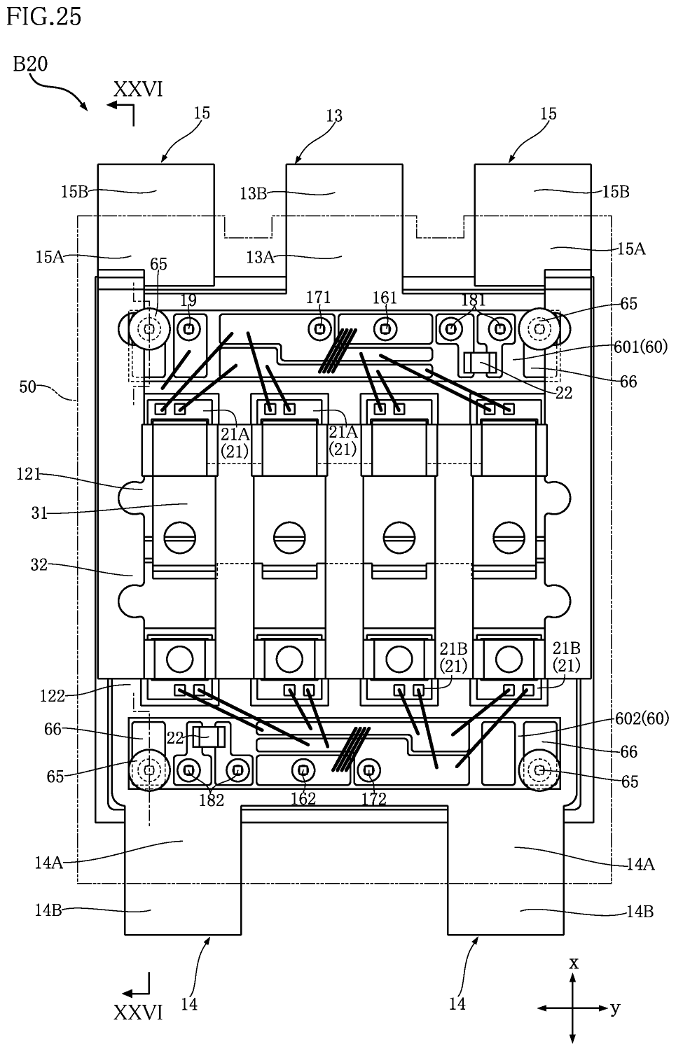

The following describes a semiconductor module A20 according to a second embodiment of the present disclosure with reference to FIGS. 23 to 26. In these figures, elements that are the same as or similar to the elements of the semiconductor module A10 and the semiconductor devices B10 described above are provided with the same reference numerals, and descriptions thereof are omitted. FIG. 25 shows the sealing resin 50 as transparent for convenience of understanding. In FIG. 25, the outline of the transparent sealing resin 50 is indicated by an imaginary line.

The semiconductor module A20 includes a plurality of semiconductor devices B20, the heat sink 70, the plurality of first wiring boards 71, the second wiring board 72, the plurality of communication wirings 73, the plurality of mounting members 74, and the plurality of positioning pins 76.

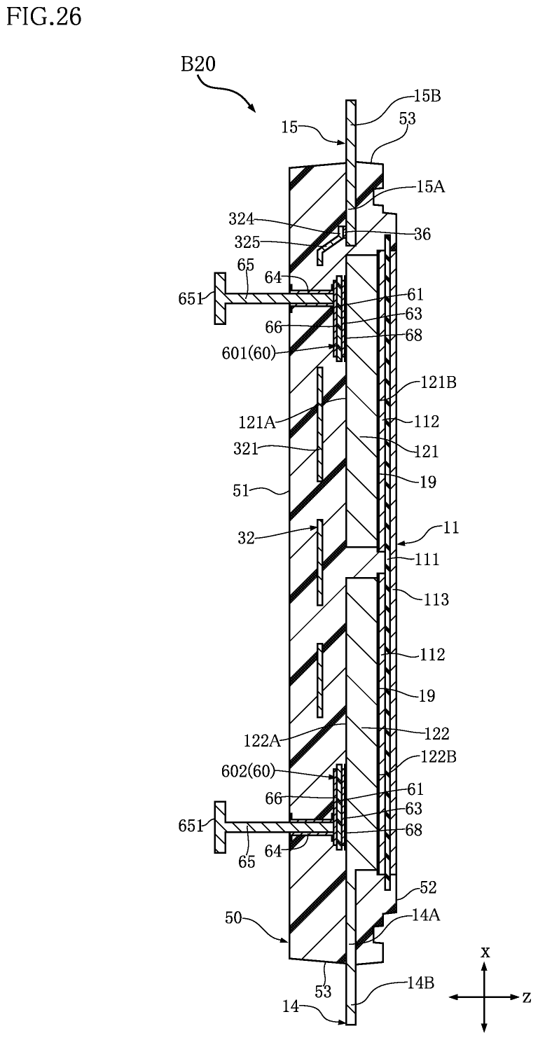

First, the semiconductor devices B20 that constitute the semiconductor module A20 will be described with reference to FIGS. 25 and 26. The semiconductor devices B20 are identical to each other. Accordingly, the description of the semiconductor devices B20 will be provided with one of the semiconductor devices B20 as a representative.

The semiconductor device B20 is different from each of the semiconductor devices B10 in further including a plurality of support pins 65. As shown in FIG. 26, the support pins 65 protrude from the top surface 51 of the sealing resin 50 in the first direction z. As shown in FIG. 25, the support pins 65 are located at both ends of each of the pair of control wirings 60 in the third direction y. Both ends of each of the pair of control wirings 60 in the third direction y are provided with a plurality of base layers 66. The base layers 66 are located on the same side as the wiring layers 62 with respect to the insulating layer 61 in the first direction z. The base layers 66 are made of the same material as the wiring layers 62. The sleeves 64 are bonded to the respective base layers 66. The sleeves 64 are bonded to the base layers 66 in the same manner as how the sleeves 64 are bonded to the wiring layers 62. The support pins 65 are press-fitted into the respective sleeves 64 bonded to the base layers 66. Thus, the support pins 65 are supported by the pair of control wirings 60.

As shown in FIG. 26, each of the support pins 65 has a seating surface 651. The seating surface 651 faces the same side as the top surface 51 of the sealing resin 50 in the first direction z. As shown in FIG. 25, the seating surface 651 of each support pin 65 is surrounded by the periphery of the sealing resin 50, as viewed in the first direction z.

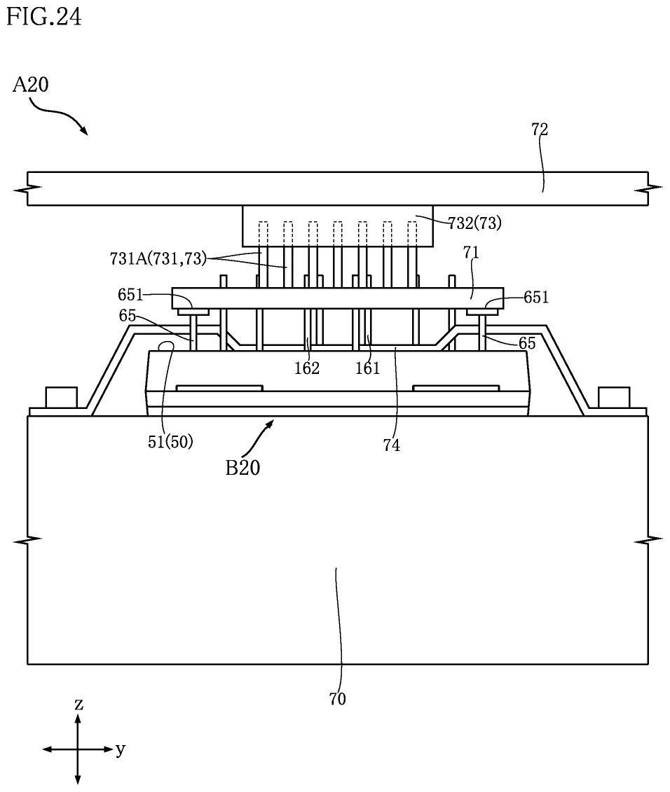

Next, the semiconductor module A20 will be described with reference to FIGS. 23 and 24. As shown in FIG. 24, each of the first wiring boards 71 is supported by the seating surfaces 651 of the support pins 65 of one of the semiconductor devices B20. As such, the semiconductor module A20 is configured without the support members 75. As shown in FIG. 23, in at least one of the semiconductor devices B20, the first wiring board 71 is surrounded by the periphery of the sealing resin 50, as viewed in the first direction z.

The following describes advantages of the semiconductor module A20.

The semiconductor module A20 includes the first wiring boards 71 electrically connected to the first signal terminals 161 of the respective semiconductor devices B20, and the second wiring board 72 electrically connected to the first wiring boards 71. The first signal terminals 161 of the semiconductor devices B20 are press-fitted into the respective first wiring boards 71 in the first direction z. In this case, the semiconductor module A20 further includes the communication wirings 73 that electrically connect the first wiring boards 71 and the second wiring board 72. The communication wirings 73 are displaceable in a direction perpendicular to the first direction z. As such, the semiconductor module A20 can also allow misalignment of the wiring board (the second wiring board 72) in a direction perpendicular to the direction in which the first signal terminals 161 extend, while connecting the wiring boards (the first wiring boards 71) more firmly to the first signal terminals 161 of the respective semiconductor devices B20. Furthermore, the semiconductor module A20 has advantages similar to the semiconductor module A10 owing to its common configuration with the semiconductor module A10.

Each of the semiconductor devices B20 constituting the semiconductor module A20 further includes support pins 65 protruding from the top surface 51 of the sealing resin 50. Each of the support pins 65 has a seating surface 651 facing the same side as the top surface 51 in the first direction z. The first wiring board 71 of the semiconductor device B20 is supported by the seating surfaces 651. As a result, as compared to the semiconductor module A10, the semiconductor module A20 does not need the support members 75. In addition, the dimensions of each first wiring board 71 can be reduced as viewed in the first direction z.

### Third Embodiment

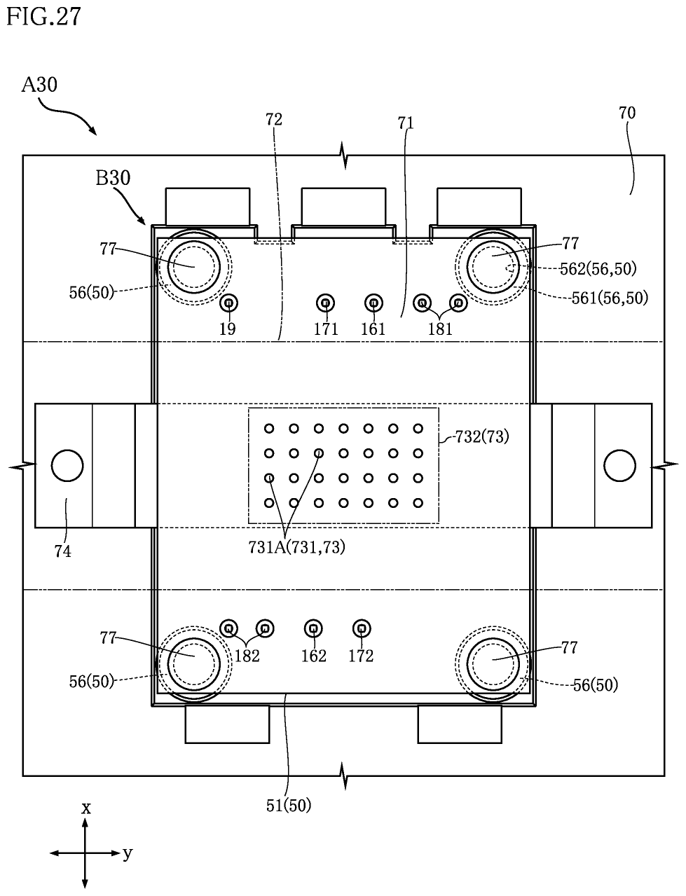

The following describes a semiconductor module A30 according to a third embodiment of the present disclosure with reference to FIGS. 27 to 31. In these figures, elements that are the same as or similar to the elements of the semiconductor module A10 and the semiconductor devices B10 described above are provided with the same reference numerals, and descriptions thereof are omitted.

The semiconductor module A30 includes a plurality of semiconductor devices B30, the heat sink 70, the plurality of first wiring boards 71, the second wiring board 72, the plurality of communication wirings 73, the plurality of mounting members 74, the positioning pins 76, and a plurality of fastening members 77.

First, the semiconductor devices B30 that constitute the semiconductor module A30 will be described with reference to FIGS. 29 to 31. The semiconductor devices B30 are identical to each other. Accordingly, the description of the semiconductor devices B30 will be provided with one of the semiconductor devices B30 as a representative.

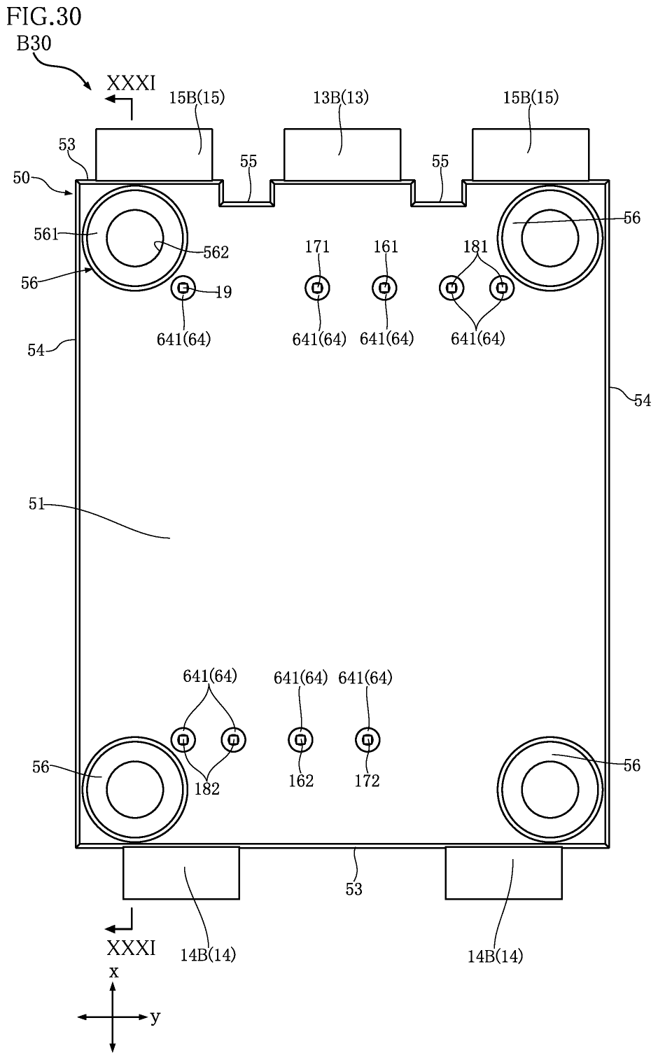

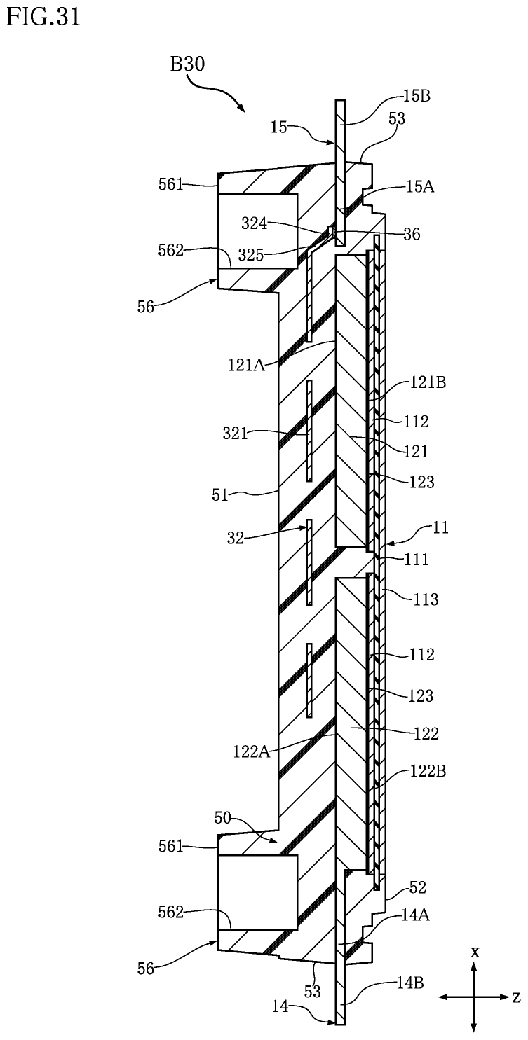

The semiconductor device B30 is different from each of the semiconductor devices B10 in the configuration of the sealing resin 50. As shown in FIG. 29, the sealing resin 50 has a plurality of pedestal portions 56. The pedestal portions 56 protrude from the top surface 51 of the sealing resin 50 in the first direction z. As shown in FIG. 30, the pedestal portions 56 are located at four corners of the sealing resin 50 as viewed in the first direction z. Each of the pedestal portions 56 has a truncated conical shape. As shown in FIGS. 30 and 31, each of the pedestal portions 56 has a support surface 561 and a mounting hole 562. The support surface 561 faces the same side as the top surface 51 in the first direction z. The mounting hole 562 is recessed from the support surface 561 in the first direction z.

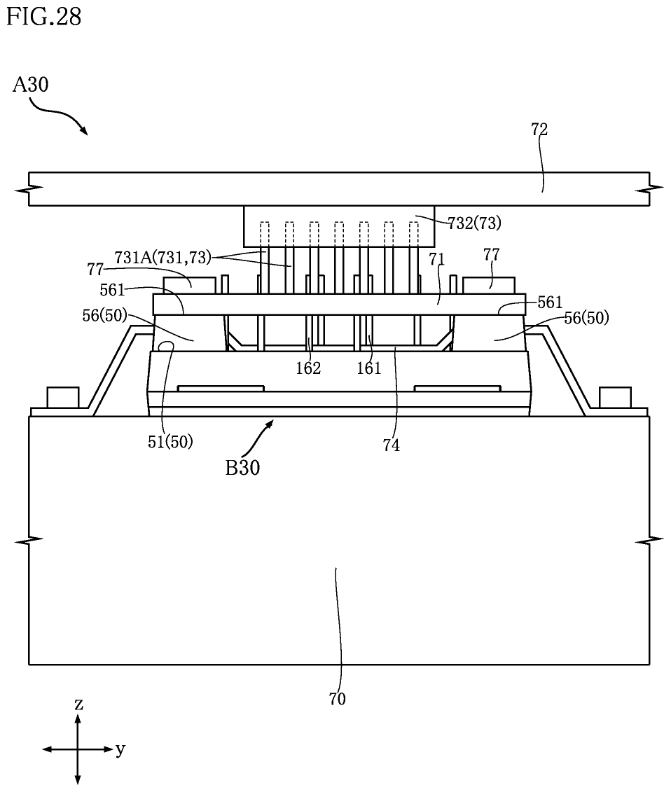

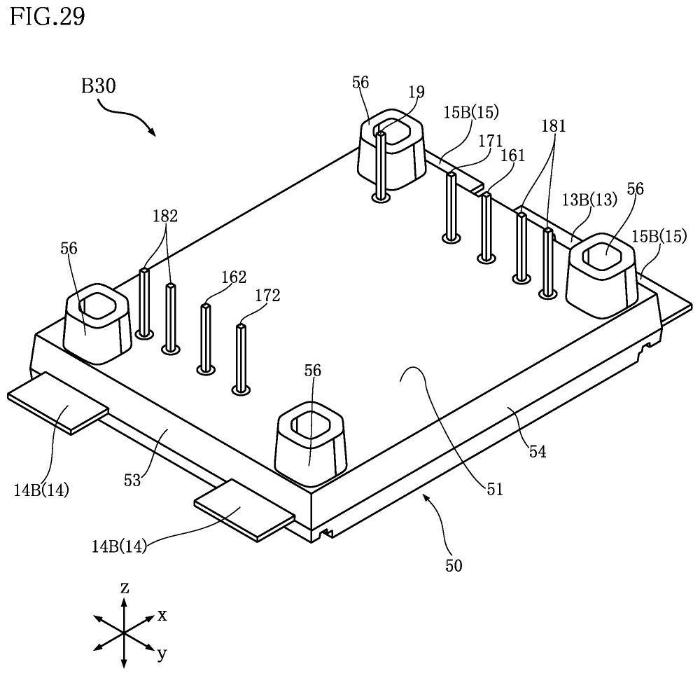

Next, the semiconductor module A30 will be described with reference to FIGS. 27 and 28. As shown in FIG. 27, as viewed in the first direction z, each of the first wiring boards 71 overlaps with the pedestal portions 56 of the sealing resin 50 of one of the semiconductor devices B30. As shown in FIG. 28, each of the first wiring boards 71 is supported by the support surfaces 561 of the pedestal portions 56 of one of the semiconductor devices B30. As such, the semiconductor module A30 is configured without the support members 75. As shown in FIG. 27, as viewed in the first direction z, at least one of the first wiring boards 71 is surrounded by the periphery of the sealing resin 50 of one of the semiconductor devices B30.

As shown in FIGS. 27 and 28, the fastening members 77 are used to attach each of the first wiring boards 71 to the pedestal portions 56 of one of the semiconductor devices B30. The fastening members 77 are bolts, for example. The fastening members 77 are inserted in the mounting holes 562 of the respective pedestal portions 56.

The following describes advantages of the semiconductor module A30.

The semiconductor module A30 includes the first wiring boards 71 electrically connected to the first signal terminals 161 of the respective semiconductor devices B30, and the second wiring board 72 electrically connected to the first wiring boards 71. The first signal terminals 161 of the semiconductor devices B30 are press-fitted into the respective first wiring boards 71 in the first direction z. In this case, the semiconductor module A30 further includes the communication wirings 73 that electrically connect the first wiring boards 71 and the second wiring board 72. The communication wirings 73 are displaceable in a direction perpendicular to the first direction z. As such, the semiconductor module A30 can also allow misalignment of the wiring board (the second wiring board 72) in a direction perpendicular to the direction in which the first signal terminals 161 extend, while connecting the wiring boards (the first wiring boards 71) more firmly to the first signal terminals 161 of the respective semiconductor devices B30. Furthermore, the semiconductor module A30 has advantages similar to the semiconductor module A10 owing to its common configuration with the semiconductor module A10.

The sealing resin 50 of each of the semiconductor devices B30 constituting the semiconductor module A30 has pedestal portions 56 protruding from the top surface 51. As viewed in the first direction z, each of the first wiring boards 71 overlaps with the corresponding pedestal portions 56. In the semiconductor module A30, each of the first wiring boards 71 is supported by the corresponding pedestal portions 56. As a result, as compared to the semiconductor module A10, the semiconductor module A30 does not need the support members 75. In addition, the dimensions of each first wiring board 71 can be reduced as viewed in the first direction z.

### Fourth Embodiment

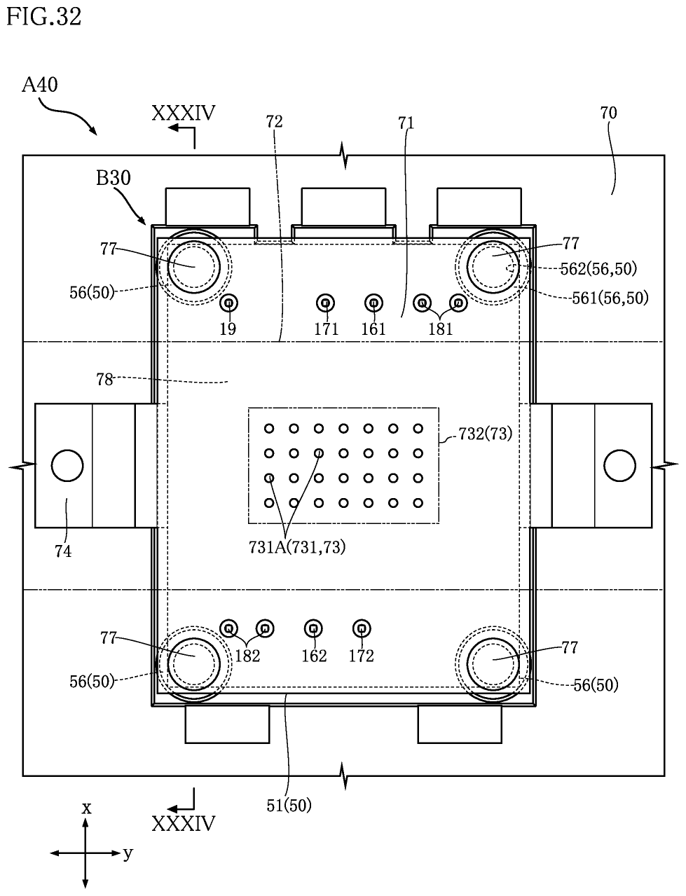

The following describes a semiconductor module A40 according to a fourth embodiment of the present disclosure with reference to FIGS. 32 to 34. In these figures, elements that are the same as or similar to the elements of the semiconductor module A10 and the semiconductor devices B10 described above are provided with the same reference numerals, and descriptions thereof are omitted.

The semiconductor module A40 is different from the semiconductor module A30 described above in further including a plurality of covers 78.

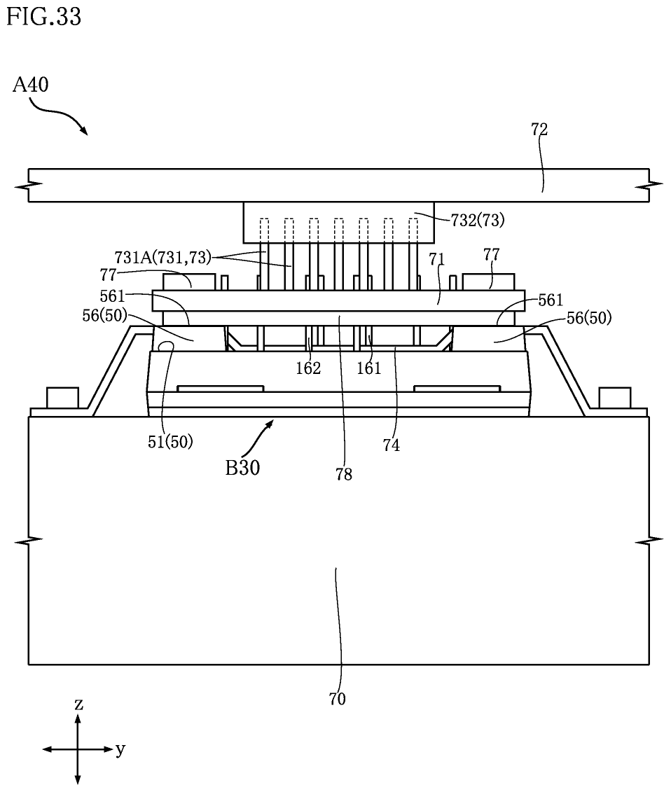

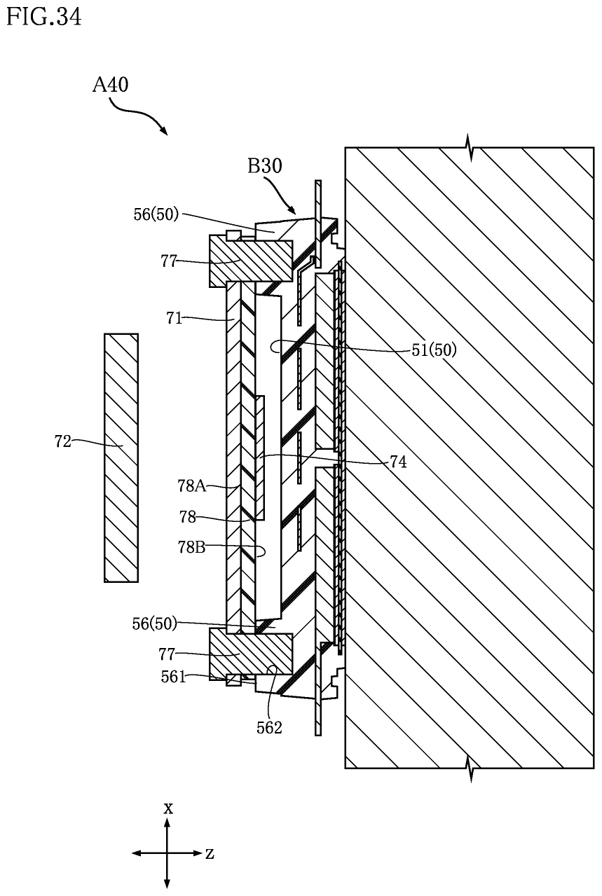

As shown in FIG. 33, each of the covers 78 is located between the top surface 51 of the sealing resin 50 of one of the semiconductor devices B30 and one of the first wiring boards 71 in the first direction z. The covers 78 are insulators. The covers 78 are made of a material containing resin, for example. As shown in FIGS. 32 to 34, each of the covers 78 extends across one of the mounting members 74. As shown in FIG. 34, each of the covers 78 has an inner surface 78A and an outer surface 78B. The inner surface 78A faces a mounting member 74. The outer surface 78B faces away from the inner surface 78A in the first direction z. The outer surface 78B faces a first wiring board 71. At least one of the mounting members 74 is in contact with one of the covers 78. Alternatively, all of the mounting members 74 may be spaced apart from the covers 78.

The first signal terminal 161, the second signal terminal 162, the third signal terminal 171, the fourth signal terminal 172, the pair of fifth signal terminals 181, the pair of sixth signal terminals 182, and the seventh signal terminal 19 of one of the semiconductor devices B30 penetrate through one of the covers 78 in the first direction z.

Each of the covers 78 is supported by the support surfaces 561 of the pedestal portions 56 of the sealing resin 50 in one of the semiconductor devices B30. Each of the first wiring boards 71 is supported by one of the covers 78. Thus, each of the covers 78 is configured to be sandwiched between the pedestal portions 56 of one of the semiconductor devices B30 and one of the first wiring boards 71. As shown in FIG. 34, each of the fastening members 77 penetrates through one of the covers 78 in the first direction z. Thus, each of the covers 78 is integrated with one of the first wiring boards 71 and mounted on the pedestal portions 56 of one of the semiconductor devices B30.

The following describes advantages of the semiconductor module A40.

The semiconductor module A40 includes the first wiring boards 71 electrically connected to the first signal terminals 161 of the respective semiconductor devices B30, and the second wiring board 72 electrically connected to the first wiring boards 71. The first signal terminals 161 of the semiconductor devices B30 are press-fitted into the respective first wiring boards 71 in the first direction z. In this case, the semiconductor module A40 further includes the communication wirings 73 that electrically connect the first wiring boards 71 and the second wiring board 72. The communication wirings 73 are displaceable in a direction perpendicular to the first direction z. As such, the semiconductor module A40 can also allow misalignment of the wiring board (the second wiring board 72) in a direction perpendicular to the direction in which the first signal terminals 161 extend, while connecting the wiring boards (the first wiring boards 71) more firmly to the first signal terminals 161 of the respective semiconductor devices B30. Furthermore, the semiconductor module A40 has advantages similar to the semiconductor module A10 owing to its common configuration with the semiconductor module A10.

The semiconductor module A40 further includes the covers 78 that are insulators each located between the top surface 51 of the sealing resin 50 of one of the semiconductor devices B30 and one of the first wiring boards 71 in the first direction z. Each of the covers 78 restrains one of the semiconductor devices B30 at the heat sink 70, and extends across one of the mounting members 74 that are conductors. This makes it possible to suppress a decrease in the dielectric strength of the first wiring boards 71 caused by the mounting members 74. Furthermore, the height of the pedestal portions 56 of the sealing resin 50 of each semiconductor device B30 can be reduced.

### Fifth Embodiment

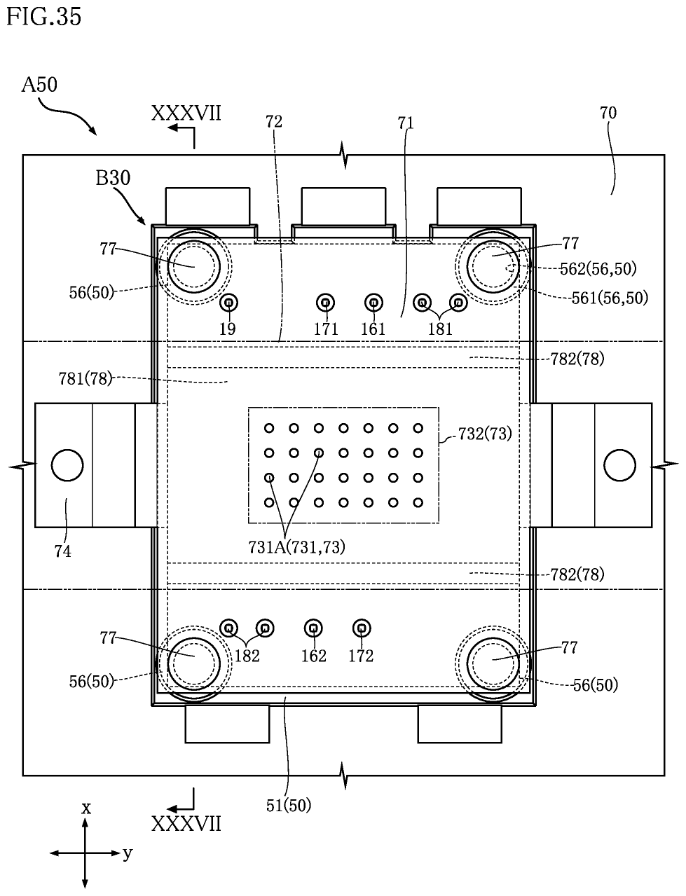

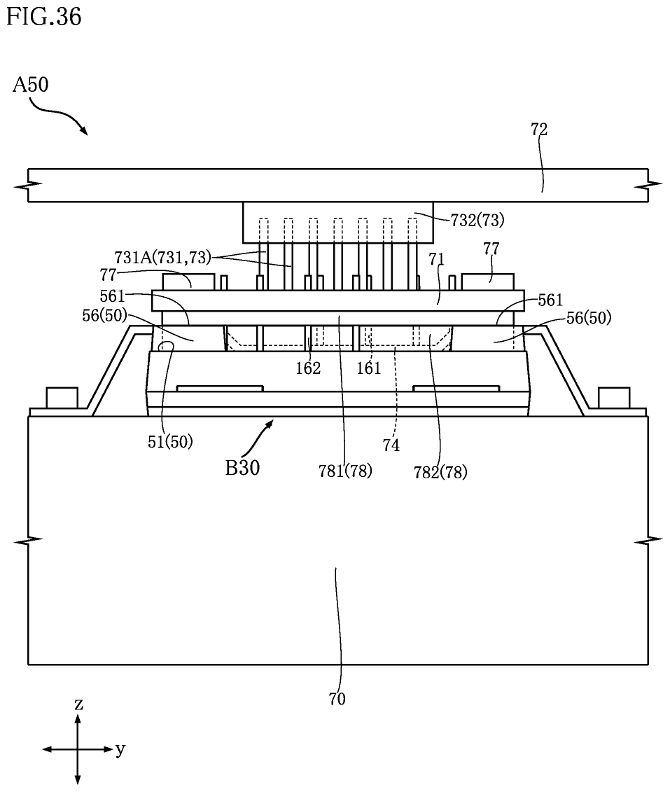

The following describes a semiconductor module A50 according to a fifth embodiment of the present disclosure with reference to FIGS. 35 to 37. In these figures, elements that are the same as or similar to the elements of the semiconductor module A10 and the semiconductor devices B10 described above are provided with the same reference numerals, and descriptions thereof are omitted.

The semiconductor module A50 is different from the semiconductor module A10 described above in the configurations of the covers 78.

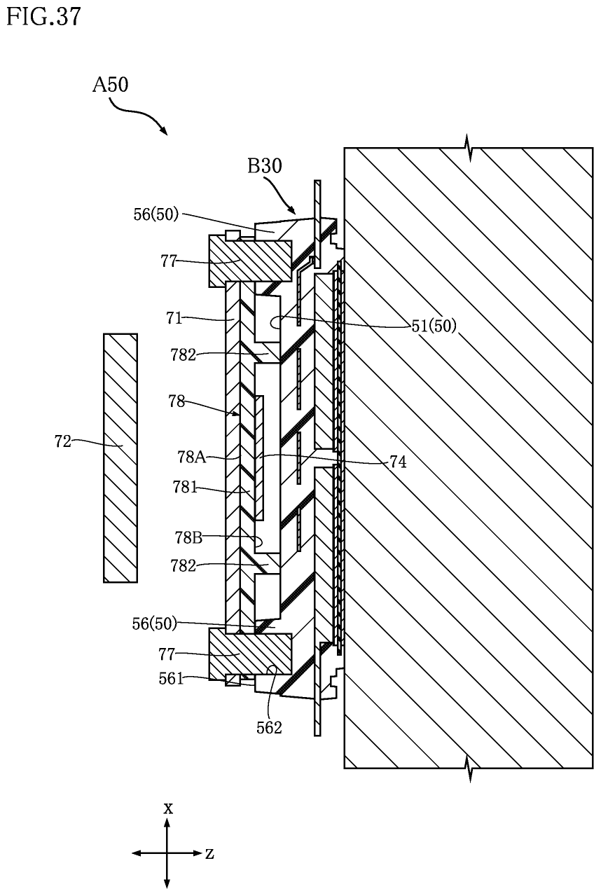

As shown in FIG. 37, each of the covers 78 has a main portion 781 and a pair of beam portions 782. The main portion 781 includes an inner surface 78A and an outer surface 78B. The main portion 781 extends across a mounting member 74. The pair of beam portions 782 protrude from the inner surface 78A in the first direction z, and extend in the third direction y. The pair of beam portions 782 are spaced apart from each other in the second direction x. One of the pair of beam portions 782 is located between a mounting member 74 and the first signal terminal 161 of one of the semiconductor devices B30 in the second direction x. The other one of the pair of beam portions 782 is located between the mounting member 74 and the second signal terminal 162 of the semiconductor device B30 in the second direction x. As a result, a portion of the mounting member 74 is surrounded by the sealing resin 50 of the semiconductor device B30, the main portion 781 of the cover 78, and the pair of beam portions 782.

The following describes advantages of the semiconductor module A50.

The semiconductor module A50 includes the first wiring boards 71 electrically connected to the first signal terminals 161 of the respective semiconductor devices B30, and the second wiring board 72 electrically connected to the first wiring boards 71. The first signal terminals 161 of the semiconductor devices B30 are press-fitted into the respective first wiring boards 71 in the first direction z. In this case, the semiconductor module A50 further includes the communication wirings 73 that electrically connect the first wiring boards 71 and the second wiring board 72. The communication wirings 73 are displaceable in a direction perpendicular to the first direction z. As such, the semiconductor module A50 can also allow misalignment of the wiring board (the second wiring board 72) in a direction perpendicular to the direction in which the first signal terminals 161 extend, while connecting the wiring boards (the first wiring boards 71) more firmly to the first signal terminals 161 of the respective semiconductor devices B30. Furthermore, the semiconductor module A50 has advantages similar to the semiconductor module A10 owing to its common configuration with the semiconductor module A10.

Each of the covers 78 in the semiconductor module A50 has a main portion 781, and a pair of beam portions 782 protruding from the inner surface 78A of the main portion 781. As a result, a portion of the mounting member 74 restraining a semiconductor device B30 at the heat sink 70 is surrounded by the sealing resin 50 of the semiconductor device B30, the main portion 781 of a cover 78, and the pair of beam portions 782 of the cover 78. This makes it possible to suppress a decrease in the dielectric strength of the first wiring boards 71 and the semiconductor devices B30 caused by the mounting member 74.

The present disclosure is not limited to the above embodiments. Various design changes can be made to the specific configurations of the elements of the present disclosure.

The present disclosure includes the embodiments according to the following clauses.

### Clause 1

A semiconductor module comprising:
a plurality of semiconductor devices including respective semiconductor elements and respective signal terminals extending in a first direction, the semiconductor elements being electrically connected to the signal terminals, respectively;
a heat sink located opposite from the signal terminals with respect to the semiconductor elements in the first direction, the heat sink supporting the plurality of semiconductor devices;
a plurality of first wiring boards that are located opposite from the heat sink with respect to the semiconductor elements in the first direction, and that are electrically connected to the signal terminals of the semiconductor devices, respectively;
a second wiring board electrically connected to the plurality of first wiring boards; and
a plurality of communication wirings electrically connecting the plurality of first wiring boards and the second wiring board,
wherein the plurality of first wiring boards are provided with first protection circuits configured to suppress application of overvoltage to the semiconductor elements,
the signal terminal of one of the plurality of semiconductor devices is press-fitted into one of the plurality of first wiring boards in the first direction, and
the plurality of communication wirings are displaceable in a direction perpendicular to the first direction.

### Clause 2

The semiconductor module according to clause 1, wherein the second wiring board is located opposite from the heat sink with the plurality of first wiring boards therebetween in the first direction.

### Clause 3

The semiconductor module according to clause 2, wherein the plurality of communication wirings include respective first connecting portions each electrically bonded to one of the plurality of first wiring boards, and respective second connecting portions electrically bonded to the second wiring board, and
the second connecting portions are displaceable relative to the first connecting portions in a direction perpendicular to the first direction.

### Clause 4

The semiconductor module according to clause 2, wherein the plurality of communication wirings are flexible to be displaced in a direction perpendicular to the first direction.

### Clause 5

The semiconductor module according to any of clauses 2 to 4, wherein the plurality of semiconductor devices include respective sealing resins having respective top surfaces each facing one of the plurality of first wiring boards in the first direction, the sealing resins covering the semiconductor elements, and
the signal terminals protrude from the top surfaces.

### Clause 6

The semiconductor module according to clause 5, further comprising a mounting member that restrains one of the plurality of semiconductor devices to the heat sink,
wherein the mounting member is in contact with the top surface.

### Clause 7

The semiconductor module according to clause 6, wherein the mounting member extends across the top surface.

### Clause 8

The semiconductor module according to clause 6 or 7, further comprising a support member located between the heat sink and one of the plurality of first wiring boards in the first direction,
wherein one of the plurality of first wiring boards is supported by the support member, and
as viewed in the first direction, the support member is spaced apart from the top surface.

### Clause 9

The semiconductor module according to clause 6 or 7, wherein one of the plurality of semiconductor devices further includes a support pin protruding from the top surface,
the support pin includes a seating surface facing a same side as the top surface in the first direction, and
one of the plurality of first wiring boards is supported by the seating surface.

### Clause 10

The semiconductor module according to clause 6 or 7, wherein the sealing resin includes a pedestal portion protruding from the top surface, and
as viewed in the first direction, one of the plurality of first wiring boards overlaps with the pedestal portion.

### Clause 11

The semiconductor module according to clause 10, wherein one of the plurality of first wiring boards is supported by the pedestal portion.

### Clause 12

The semiconductor module according to clause 10, further comprising a cover that is an insulator located between the top surface and one of the plurality of first wiring boards in the first direction, and
the cover extends across the mounting member.

### Clause 13

The semiconductor module according to clause 12, wherein the cover is supported by the pedestal portion, and
one of the plurality of first wiring boards is supported by the cover.

### Clause 14

The semiconductor module according to clause 12 or 13, wherein the mounting member is in contact with the cover.

### Clause 15

The semiconductor module according to any of clauses 6 to 14, wherein the mounting member is a conductor.

### Clause 16

The semiconductor module according to any of clauses 6 to 15, wherein each of the plurality of semiconductor elements includes a first element and a second element,
the signal terminals include a first signal terminal electrically connected to the first element, and a second signal terminal electrically connected to the second element, and
the mounting member is located between the first signal terminal and the second signal terminal in a second direction perpendicular to the first direction.

### Clause 17

The semiconductor module according to any of clauses 1 to 16, wherein the plurality of first wiring boards are provided with a second protection circuit configured to suppress application of surge voltage to the semiconductor element, and
the plurality of first wiring boards are provided with a gate driver that is electrically connected to the first protection circuit and the second protection circuit, and that drives the semiconductor elements.

### REFERENCE NUMERALS

A10, A20, A30, A40, A50: Semiconductor module
B10, B20, B30: Semiconductor device 11: Support
111: Insulating layer 112: Intermediate layer
113: Heat dissipation layer 121: First conductive layer
121A: First obverse surface 121B: First reverse surface
122: Second conductive layer 122A: Second obverse surface
122B: Second reverse surface 123: First adhesive layer
13: First input terminal 13A: Covered portion
14A: Covered portion 14B: Exposed portion
13B: Exposed portion 14: Output terminal
15: Second input terminal 15A: Covered portion
15B: Exposed portion 161: First signal terminal
161A: Base 161B: Bulging portion
161C: Seating portion 162: Second signal terminal
171: Third signal terminal 172: Fourth signal terminal
181: Fifth signal terminal 182: Sixth signal terminal
19: Seventh signal terminal 21: Semiconductor element
21A: First element 21B: Second element
211: First electrode 212: Second electrode
213: Third electrode 214: Fourth electrode
22: Thermistor 23: Conductive bonding layer
31: First conducting member 311: Main body
312: First bonding portion 313: First connecting portion
314: Second bonding portion 315: Second connecting portion
32: Second conducting member 321: Main body
322: Third bonding portion 323: Third connecting portion
324: Fourth bonding portion 325: Fourth connecting portion
326: Intermediate portion 327: beam portion
33: First conductive bonding layer
34: Second conductive bonding layer
35: Third conductive bonding layer
36: Fourth conductive bonding layer
41: First wire 42: Second wire
43: Third wire 44: Fourth wire
50: Sealing resin 51: Top surface
52: Bottom surface 53: First side surface
54: Second side surface 55: Recess
56: Pedestal portion 561: Support surface
562: Mounting hole 60: Control wiring
601: First wiring 602: Second wiring
61: Insulating layer 62: Wiring layer
621: First wiring layer 622: Second wiring layer
623: Third wiring layer 624: Fourth wiring layer
625: Fifth wiring layer 63: Metal layer
64: Sleeve 641: End surface
65: Support pin 651: Seating surface
66: Base layer 68: Second adhesive layer
69: Third adhesive layer 70: Heat sink
71: First wiring board 711: Substrate
711A: Through-hole 712: Obverse wiring
713: Reverse wiring 714: Internal wiring
72: Second wiring board 73: Communication wiring
731: First connecting portion 731A: Connecting pin
731B: Housing 732: Second connecting portion
732A: Housing 732B: Connecting hole
74: Mounting member 75: Support member
76: Positioning pin 77: Fastening member
78: Cover 78A: Inner surface
78B: Outer surface 781: Main portion
782: Beam portion 81: First protection circuit
82: Second protection circuit 83: Gate driver
83A: First driver 83B: Second driver
84: Gate resistor z: First direction
x: Second direction y: Third direction

1. A semiconductor module comprising:
a plurality of semiconductor devices including respective semiconductor elements and respective signal terminals extending in a first direction, the semiconductor elements being electrically connected to the signal terminals, respectively;
a heat sink located opposite from the signal terminals with respect to the semiconductor elements in the first direction, the heat sink supporting the plurality of semiconductor devices;
a plurality of first wiring boards that are located opposite from the heat sink with respect to the semiconductor elements in the first direction, and that are electrically connected to the signal terminals of the semiconductor devices, respectively;
a second wiring board electrically connected to the plurality of first wiring boards; and
a plurality of communication wirings electrically connecting the plurality of first wiring boards and the second wiring board,
wherein the plurality of first wiring boards are provided with first protection circuits configured to suppress application of overvoltage to the semiconductor elements,
the signal terminal of one of the plurality of semiconductor devices is press-fitted into one of the plurality of first wiring boards in the first direction, and
the plurality of communication wirings are displaceable in a direction perpendicular to the first direction.

2. The semiconductor module according to claim 1, wherein the second wiring board is located opposite from the heat sink with the plurality of first wiring boards therebetween in the first direction.

3. The semiconductor module according to claim 2, wherein the plurality of communication wirings include respective first connecting portions each electrically bonded to one of the plurality of first wiring boards, and respective second connecting portions electrically bonded to the second wiring board, and
the second connecting portions are displaceable relative to the first connecting portions in a direction perpendicular to the first direction.

4. The semiconductor module according to claim 2, wherein the plurality of communication wirings are flexible to be displaced in a direction perpendicular to the first direction.

5. The semiconductor module according to claim 2, wherein the plurality of semiconductor devices include respective sealing resins having respective top surfaces each facing one of the plurality of first wiring boards in the first direction, the sealing resins covering the semiconductor elements, and
the signal terminals protrude from the top surfaces.

6. The semiconductor module according to claim 5, further comprising a mounting member that restrains one of the plurality of semiconductor devices to the heat sink,
wherein the mounting member is in contact with the top surface.

7. The semiconductor module according to claim 6, wherein the mounting member extends across the top surface.

8. The semiconductor module according to claim 6, further comprising a support member located between the heat sink and one of the plurality of first wiring boards in the first direction,
wherein one of the plurality of first wiring boards is supported by the support member, and
as viewed in the first direction, the support member is spaced apart from the top surface.

9. The semiconductor module according to claim 6, wherein one of the plurality of semiconductor devices further includes a support pin protruding from the top surface,
the support pin includes a seating surface facing a same side as the top surface in the first direction, and
one of the plurality of first wiring boards is supported by the seating surface.

10. The semiconductor module according to claim 6, wherein the sealing resin includes a pedestal portion protruding from the top surface, and
as viewed in the first direction, one of the plurality of first wiring boards overlaps with the pedestal portion.

11. The semiconductor module according to claim 10, wherein one of the plurality of first wiring boards is supported by the pedestal portion.

12. The semiconductor module according to claim 10, further comprising a cover that is an insulator located between the top surface and one of the plurality of first wiring boards in the first direction, and
the cover extends across the mounting member.

13. The semiconductor module according to claim 12, wherein the cover is supported by the pedestal portion, and
one of the plurality of first wiring boards is supported by the cover.

14. The semiconductor module according to claim 12, wherein the mounting member is in contact with the cover.

15. The semiconductor module according to claim 6, wherein the mounting member is a conductor.

16. The semiconductor module according to claim 6, wherein each of the plurality of semiconductor elements includes a first element and a second element,
the signal terminals include a first signal terminal electrically connected to the first element, and a second signal terminal electrically connected to the second element, and
the mounting member is located between the first signal terminal and the second signal terminal in a second direction perpendicular to the first direction.

17. The semiconductor module according to claim 1, wherein the plurality of first wiring boards are provided with a second protection circuit configured to suppress application of surge voltage to the semiconductor element, and
the plurality of first wiring boards are provided with a gate driver that is electrically connected to the first protection circuit and the second protection circuit, and that drives the semiconductor elements.
